(19) United States
(12) Patent Application Publication
(10) Pub. No.: US 2008/0111182 A1
(43) Pub. Date: May 15, 2008

(54) Forming buried contact etch stop layer (CESL) in semiconductor devices self-aligned to diffusion

(76) Inventors: Rustom Irani, Santa Clara, CA (US); Assaf Shappir, Kiryat Ono (IL)

Correspondence Address: EMPK & Shiloh, LLP, 116 JOHN ST,, SUITE 1201, NEW YORK, NY, 10038, US

(21) Appl. No.: 11/979,314

(22) Filed: Nov. 1, 2007

Related U.S. Application Data
(60) Provisional application No. 60/856,025, filed on Nov. 2, 2006.

(51) Int. Cl. H01L 29/792

(52) U.S. Cl. 257/324; 257/E29.309

(57) ABSTRACT

A buried contact etch stop layer (CESL) is disposed between adjacent diffusions in a semiconductor device, such as between bitlines in a memory array. The CESL may be self-aligned to the diffusions, and may prevent misaligned bitline (BL) contacts from contacting silicon outside of the corresponding bitlines. The bitline contacts may have sufficient overlap of the bitlines to ensure full coverage by the bitlines. STI trenches may optionally be formed under the CESL. The CESL may comprise nitride or any other material that is harder (more resistant) to etch than the material on top of it.

### CROSS-REFERENCE(S) TO RELATED APPLICATION(S)

This application claims the benefit of U.S. Provisional Application No. 60/856,025, filed Nov. 2, 2006, the entire disclosure of which is incorporated herein by reference.

### BACKGROUND

1. Technical Field

The disclosure relates to techniques for fabricating semiconductor devices and, more particularly, to forming arrays of non-volatile memory (NVM) cells.

2. The Field Effect Transistor

The transistor is a solid state semiconductor device which can be used for amplification, switching, voltage stabilization, signal modulation and many other functions. Generally, a transistor has three terminals, and a voltage applied to a specific one of the terminals controls current flowing between the other two terminals.

The terminals of a field effect transistor (FET) are commonly named source, gate and drain. In the FET a small amount of voltage is applied to the gate in order to control current flowing between the source and drain. In FETs the main current appears in a narrow conducting channel formed near (usually primarily under) the gate. This channel connects electrons from the source terminal to the drain terminal. The channel conductivity can be altered by varying the voltage applied to the gate terminal, enlarging or constricting the channel and thereby controlling the current flowing between the source and the drain.

FIG. 1 illustrates a FET 100 comprising a p-type substrate, and two spaced-apart n-type diffusion areas-one of which will serve as the “source”, the other of which will serve as the “drain” of the transistor. The space between the two diffusion areas is the “channel”. A thin dielectric layer is disposed over the substrate in the neighborhood of the channel, and a “gate” structure is disposed over the dielectric layer atop the channel. (The dielectric tinder the gate is also commonly referred to as “gate oxide” or “gate dielectric”.) Electrical connections (not shown) may be made to the source, the drain, and the gate. The substrate may be grounded.

Generally, when there is no voltage on the gate, there is no electrical conduction (connection) between the source and the drain. As voltage (of the correct polarity) is applied to the gate, there is a “field effect” in the channel between the source and the drain, and current can flow between the source and the drain, and can be controlled by the voltage applied to the gate. In this manner, a small signal (gate voltage) can control a relatively large signal (current flow between the source and the drain).

The Floating Gate Transistor

A floating gate transistor is generally a transistor structure, broadly based oil the FET, as described hereinabove. As illustrated in FIG. 2, the floating gate transistor 200 has a source and a drain, but rather than having only one gate, it has two gates which are called control gate (CG) and floating gate (FG). It is this arrangement of control gate and floating gate which enables the floating gate transistor to function as a memory cell, as described hereinbelow.

The floating gate is disposed over tunnel oxide (comparable to the gate oxide of the FET). The floating gate is a conductor, while the tunnel oxide is an insulator (dielectric material). Another layer of oxide (interpoly oxide, also a dielectric material) separates the floating gate from the control gate.

Since the floating gate is a conductor, and is surrounded by dielectric material, it can store a charge. Electrons can move around freely within the conductive material of the floating gate (which comports with the basic definition of a “conductor”).

Since the floating gate can store a charge, it can exert a field effect on the channel region between the source and the drain, in a manner similar to how a normal FET works, as described hereinabove. Mechanisms for storing charges on the floating gate structure, as well as removing charges from the floating gate are described hereinbelow.

Generally, if a charge is stored on the floating gate, this represents a binary “1”. If no charge is stored on the floating gate, this represents a binary “0”. (These designations are arbitrary, and can be reversed so that the charged state represents binary “0” and the discharged state represents binary “1”.) That represents the programming “half” of how a floating gate memory cell operates. The other half is how to determine whether there is a charge stored on the floating gate—in other words, to “read” the memory cell. Generally, this is done by applying appropriate voltages to the source, drain and gate terminals, and determining how conductive the channel is. Some modes of operation for a floating gate memory cell are described hereinbelow.

Normally, the floating gate non-volatile memory (NVM) cell has only a single “charge-storing area”—namely, the conductive floating gate (FG) structure, and can therefore only store a single bit of information (binary “1” or binary “0”). More recently, using a technology referred to as “multi-level cell” (MLC), two or more bits can be stored in and read from the floating gate cell.

The NROM Memory Cell

Another type of memory cell, called a “nitride, read only memory” (NROM) cell, has a charge-storage structure which is different from that of the floating gate memory cell and which permits charges to be stored in two separate charge-storage areas. Generally, the two separate charge storage areas are located within a non-conductive layer disposed between the gate and the underlying substrate, such as a layer of nitride formed in an oxide-nitride-oxide (ONO) stack underneath the gate. The non-conductive layer acts as a charge-trapping medium. Generally, electrical charges will stay where they are put in the charge-trapping medium, rather than being free to move around as in the example of the conductive floating gate of the floating gate memory cell. A first bit of binary information (binary “1” or binary “0”) can be stored in a first portion (such as the left-hand side) of the charge-trapping medium, and a second bit of binary information (binary “1” or binary “0”) can be stored in a second portion (such as the right-hand side) of the charge-trapping medium. An alternative viewpoint is that different charge concentrations can be considered for each bit of storage. Using MLC technology, at least two bits can be stored in and read from each of the two portions (charge storage areas) of the charge-trapping medium (for a total of 4 bits), similarly 3 bits or more than 4 bits may be identified.

FIG. 3 illustrates a basic NROM memory cell 300, which may be viewed as an FET with an “ONO” structure inserted between the gate and the substrate. (One might say that the ONO structure is “substituted” for the gate oxide of the FET.)

The ONO structure is a stack (or “sandwich”) of bottom (lower) oxide 322, a charge-trapping material such as nitride 324, and a top (upper) oxide 326. The ONO structure may have an overall thickness of approximately 10-25 nm, such as 18 nm, as follows:
the bottom oxide layer 322 may be from 3 to 6 nm, for example 4 nm thick;
the middle nitride layer 324 may be from 3 to 8 nm, for example 4 nm thick; and
the top oxide layer 326 may be from 5 to 15 nm, for example 10 nm thick.

The NROM memory cell has two spaced apart diffusions 314 and 316 (which can function as source and drain, as discussed hereinbelow), and a channel region 320 defined in the substrate 312 between the two diffusion regions 314 and 316, and a gate 328 disposed above the ONO stack 321.

In FIG. 3, the diffusions are labeled “N+”. This means that they are regions in the substrate that have been doped with an electron donor material, such as phosphorous or arsenic. These diffusions are typically created in a larger region which is a p-type cell well (CW) doped with boron (or indium or both). This is the normal “polarity” for an NVM cell employing electron injection (but which may also employ hole injection, such as for erase). With opposite polarity (boron or indium implants in a n-type cell well), the primary injection mechanism would be for holes, which is generally accepted to be not as effective as electron injection. One skilled in the art will recognize that the concepts disclosed herein can be applied to opposite polarity devices.

The charge-trapping material 324 is non-conductive, and therefore, although electrical charges can be stored in the charge-trapping material, they are not free to move around, and they will generally stay where they are stored. Nitride is a suitable charge-trapping material. Charge trapping materials other than nitride may also be suitable for use as the charge-trapping medium. One such material is silicon dioxide with buried polysilicon islands. A layer (324) of silicon dioxide with polysilicon islands would be sandwiched between the two layers of oxide (322) and (326). Alternatively, the charge-trapping layer 324 may be constructed by implanting an impurity, such as arsenic, into a layer of silicon dioxide deposited on top of the bottom oxide 322.

The memory cell 300 is generally capable of storing at least two bits of data—at least one bit(s) in a first storage area of the nitride layer 324 represented by the dashed circle 323, and at least one bit(s) in a second storage area of the nitride layer 324 represented by the dashed circle 321. Thus, the NROM memory cell can be considered to comprise two “half cells”, each half cell capable of storing at least one bit(s). It should be understood that a half cell is not a physically separate structure from another half cell in the same memory cell. The term “half cell”, as it may be used herein, is used herein only to refer to the “left” or “right” bit storage area of the ONO stack (nitride layer). The storage areas 321, 323 may variously be referred to as “charge storage areas”, “charge trapping areas”, and the like, throughout this document. (The two charge storage areas may also be referred to as the right and left “bits”.)

Each of the storage areas 321, 323 in the charge-trapping material 324 can exert a field effect on the channel region 320 between the source and the drain, in a manner similar to how a normal FET works, as described hereinabove (FIG. 2).

Generally, if a charge is stored in a given storage area of the charge-trapping material, this represents a binary “1”, and if no charge is stored in a given storage area of the charge-trapping material, this represents a binary “0”. (Again, these designations are arbitrary, and can be reversed to that the charged state represents binary “0” and the discharged state represents binary “1”.) That represents the programming “half” of how an NROM memory cell operates. The other half is how to determine whether there is a charge stored in a given storage area of the charge-trapping material—in other words, to “read” the memory cell. Generally, this is done by applying appropriate voltages to the diffusion regions (functioning as source and drain) and gate terminals, and determining how conductive the channel is.

Generally, one feature of NROM cells is that rather than performing “symmetrical” programming and reading, NROM cells are beneficially programmed and read “asymmetrically”, which means that programming and reading occur in opposite directions. The arrows labeled in FIG. 3 are arranged to illustrate this point. Programming may be performed in what is termed the “forward” direction and reading may be performed in what is termed the “opposite” or “reverse” direction.

“Reading” an NROM Cell

Reading an NROM memory cell may involve applying voltages to the terminals of the memory cell comparable to those used to read a floating gate memory cell, but reading may be performed in a direction opposite to that of programming. Generally, rather than performing “symmetrical” programming and reading (as is the case with the floating gate memory cell, described hereinabove), the NROM memory cell is usually programmed and read “asymmetrically”, meaning that programming and reading occur in opposite directions. This is illustrated by the arrows in FIG. 3. Programming is performed in what is termed the forward direction and reading is performed in what is termed the opposite or reverse direction. For example, generally, to program the right storage area 323 (in other words, to program the right “bit”), electrons flow from left (source) to right (drain). To read the right storage area 323 (in other words, to read the right “bit”), voltages are applied to cause electrons to flow from right to left, in the opposite or reverse direction. For example, generally, to program the left storage area 321 (in other words, to program the left “bit”), electrons flow from right (source) to left (drain). To read the left storage area 321 (in other words, to read the left “bit”), voltages are applied to cause electrons to flow from left to right, in the opposite or reverse direction. See, for example, U.S. Pat. No. 6,768,165.

Memory Array Architecture, Generally

Memory arrays are well known, and comprise a plurality (many, including many millions) of memory cells organized (including physically arranged) in rows (usually represented in drawings as going across the page, horizontally, from left-to-right) and columns (usually represented in drawings as going up and down the page, from top-to-bottom).

As discussed hereinabove, each memory cell comprises a first diffusion (functioning as source or drain), a second diffusion (functioning as drain or source) and a gate, each of which has to receive voltage in order for the cell to be operated, as discussed hereinabove. Generally, the first diffusions (usually designated “source”) of a plurality of memory cells are connected to a first bit line which may be designated “BL(n)”, and second diffusions (usually designated “drain”) of the plurality of memory cells are connected to a second bit line which may be designated “BL(n+1)”. Typically, the gates of a plurality of memory cells are connected to common word lines (WL).

The bitlines may be “buried bitline” diffusions in the substrate, and may serve as the source/drain diffusions for the memory cells. The wordlines may be polysilicon structures and may serve as the gate elements for the memory cells.

FIG. 4 illustrates an array of NROM memory cells (labeled “a” through “i”) connected to a number of word lines (WL) and bit lines (BL). For example, the memory cell “e” has its gate connected to WL(n), its source (left hand diffusion) is connected to BL(n), and its drain (right hand diffusion) is connected to BL(n+1). The nine memory cells illustrated in FIG. 4 are exemplary of many millions of memory cells that may be resident on a single chip.

Notice, for example that the gates of the memory cells “e” and “f” (to the right of “e”) are both connected to the same word line WL(n). (The gate of the memory cell “d” to the left of “e” is also connected to the same word line WL(n).) Notice also that the right hand terminal (diffusion) of memory cell “e” is connected to the same bit line BL(n+1) as the left-hand terminal (diffusion) of the neighboring memory cell “f”. In this example, the memory cells “e” and “f” have two of their three terminals connected together.

The situation of neighboring memory cells sharing the same connection—the gates of neighboring memory cells being connected to the same word line, the source (for example, right hand diffusion) of one cell being connected to the drain (for example left hand diffusion) of the neighboring cell—is even more dramatically evident in what is called “virtual ground architecture” wherein two neighboring cells actually share the same diffusion. In virtual ground array architectures, the drain of one memory cell may actually be the same diffusion which is acting as the source for its neighboring cell Examples of virtual ground array architecture may be found in U.S. Pat. Nos. 5,650,959; 6,130,452; and 6,175,519, incorporated in their entirety by reference herein.

As described hereinabove, an NROM memory cell may have two spaced apart diffusions functioning as source and drain, depending on the operation (erase, program, read) being performed. For purposes of this description, the two diffusions may be referred by their orientation in an array, as either the “left” (or “left hand”) diffusion and the “right” (or “right hand”) diffusion. The drawings included herewith reflect these orientations.

In a semiconductor memory array architecture (including, but not limited to NROM), a plurality of memory cells may be arranged in rows (such as horizontal) and columns (such as vertical, or at 90 degrees to horizontal).

Bit Lines (BL, bitline) typically extend vertically through the array, and may optionally be “buried bitlines” (BB), meaning that they are formed within, rather than atop the silicon (wafer). Word Lines (WL, wordline) typically extend horizontally through the array, and may be formed optionally by polysilicon lines formed atop the surface of the wafer (atop underlying memory cell structure).

Typically, a given memory cell is connected by its two (left and right) diffusions to two adjacent bitlines, and by its gate to a single wordline. Many memory cells in a given row of the array may have their gates connected to a common wordline. Many memory cells in a given column of the array may have their left diffusion connected to a given bitline, and their right diffusion connected to another bitline.

In a typical virtual ground memory array architecture (including, but not limited to NROM), the right diffusion of a given memory cell may also be the left diffusion of an adjacent memory cell disposed immediately to the right of the given memory cell. And, that shared diffusion may run vertically through the array and function as a bitline for the two adjacent memory cells.

In a typical semiconductor memory array architecture (including, but not limited to NROM), a group of rows of memory cells, and associated wordlines, may be spaced apart from another group of rows of memory cells, and associated wordlines, leaving a “contact area” (or “contact region”). The regions populated by memory cells may be referred to as a “cell area” (or “cell region”).

Generally, the purpose of the contact region, which is not populated with memory cells, is to provide an area, not populated by memory cells, where contacts can be formed between overlying interconnect lines, to the buried bitlines. For example, a cell region may comprise 32 rows of memory cells. In a memory cell array, there are typically many cell regions separated by many contact regions. Bitline resistance is an issue determining how many rows of memory cells can be between contact regions.

Bit line contacts are essentially vias (holes), formed through any structures or layers on the substrate, such as inter-layer dielectric (ILD), and filled with a conductive material, such as metal, so that connections may be made to the bitlines to control the operation of the memory cells in the array.

An issue being addressed by the present disclosure is dealing with misalignments which may occur when forming bitline contacts to bitlines.

Since the bitlines may be spaced very close together, it is known to provide silicon trench isolation (STI) between adjacent bitlines. Generally, STI is a trench formed in the surface of the silicon and filled with an insulating material, such as oxide. Therefore, if a contact is slightly misaligned, the misaligned portion of the contact falls on oxide, and will not be a problem.

A factor which is relevant to the present disclosure, as it relates to fabrication processes targeted at the memory array, is that generally, an overall memory array (or an integrated circuit (IC) chip which comprises a memory array) has what may be referred to as an “array area” and a “periphery area” (or “peripheral area”). The array area is that area (of the chip) which is populated by memory cells (cell region) and contacts (contact region), as described hereinabove. The periphery area contains control circuitry, typically CMOS, for operating the memory array and for interfacing the memory chip with an external system, including (for example), bond pads, buffers, registers and select circuitry. It is generally desirable that any fabrication (process) steps which are being performed in the array area are compatible with fabrication (process) steps which are being performed in the periphery area.

FIG. 4A illustrates, very generally, an exemplary overall physical layout of an NVM memory chip 450 having two distinct areas—a first “Array” area (generally designated “452”) which contains the memory cells, wordlines, and bitlines (such as schematically illustrated in FIG. 4), and a second “CMOS” area (generally designated “454”; also referred to as “periphery” area) containing control circuits (not shown) which exercise control over the individual memory cells via the wordlines and bitlines connecting the memory cells. The Array Area 452 may be split into two Array Areas 452a and 452b, with a narrow CMOS area 454a extending vertically between the two Array Areas, and connecting to wordlines horizontally traversing the Array Areas. A region 454b of CMOS circuitry may be arranged horizontally across the top(s) of the Array Area(s), for connecting to the top ends of the bitlines. Another region 454c of CMOS circuitry may be arranged horizontally across the bottom(s) of the Array Area(s), for connecting to the bottom ends of the bitlines. Input and Output circuitry, buffers and bond pads may be disposed in the CMOS area for interfacing the memory chip to an external system (not shown). Generally, the purpose of this figure is simply to show that CMOS circuitry is typically implemented on the same integrated circuit (IC) chip as the memory cells and array, and therefore, processes which affect one (such as CMOS) may affect the other (Array).

Contact Etch Stop Layer (CESL)

FIG. 1 (FET), FIG. 2 (floating gate) and FIG. 3 (NROM), above, are somewhat stylized, omitting various common elements for the sake of illustrative clarity.

For example, a thin layer of metal silicide, such as cobalt silicide or titanium silicide or nickel salicide, may be formed atop the gate structure, and atop the source and drain diffusions (or two “agnostic” diffusions of an NROM cell). A dielectric layer may then be disposed over the entire device, to support upper level metalization such as wiring patterns, interconnects, word lines and bitlines which pass between several devices, as well as to external circuitry (not shown). This dielectric layer may be referred to as an inter level dielectric (ILD) layer.

Contacts must be opened through the ILD, to access the metal silicide, and effect contact with the gate (such as 328) and the two diffusions (such as 314 and 316). With reference to the diffusions, it is particularly important that, in the process of creating the contact, the underlying diffusion is not damaged. It is thereby known, and is common practice to first form a capping layer over the device, and said capping layer may act as an etch stop layer when etching the ILD to form the contacts.

The etch stop layer may be referred to hereinafter as a contact etch stop layer (CESL), and normally comprises material with good etch selectivity between the material and the Inter Layer Dielectric (ILD) through which the contact opening must be made. Nitride is an example of such a material.

Commonly-owned patents disclose structure and operation of NROM and related ONO memory cells. Some examples may be found in commonly-owned U.S. Pat. Nos. 5,768,192 and 6,011,725, 6,649,972 and 6,552,387.

Commonly-owned patents disclose architectural aspects of an NROM and related ONO array, (some of which have application to other types of NVM array) such as segmentation of the array to handle disruption in its operation, and symmetric architecture and non-symmetric architecture for specific products, as well as the use of NROM and other NVM array(s) related to a virtual ground array. Some examples may be found in commonly-owned U.S. Pat. Nos. 5,963,465, 6,285,574 and 6,633,496.

Commonly-owned patents also disclose additional aspects at the architecture level, including peripheral circuits that may be used to control an NROM array or the like. Some examples may be found in commonly-owned U.S. Pat. Nos. 6,233,180, and 6,448,750.

Commonly-owned patents also disclose several methods of operation of NROM and similar arrays, such as algorithms related to programming, erasing, and/or reading such arrays. Some examples may be found in commonly-owned U.S. Pat. Nos. 6,215,148, 6,292,394 and 6,477,084.

Commonly-owned patents also disclose manufacturing processes, such as the process of forming a thin nitride layer that traps hot electrons as they are injected into the nitride layer. Some examples may be found in commonly-owned U.S. Pat. Nos. 5,966,603, 6,030,871, 6,133,095 and 6,583,007.

Commonly-owned patents also disclose algorithms and methods of operation for each segment or technological application, such as: fast programming methodologies in all flash memory segments, with particular focus on the data flash segment, smart programming algorithms in the code flash and EEPROM segments, and a single device containing a combination of data flash, code flash and/or EEPROM. Some examples may be found in commonly-owned U.S. Pat. Nos. 6,954,393 and 6,967,896.

Where applicable, descriptions involving NROM are intended specifically to include related oxide-nitride technologies, including SONOS (Silicon-Oxide-Nitride-Oxide-Silicon), MNOS (Metal-Nitride-Oxide-Silicon), MONOS (Metal-Oxide-Nitride-Oxide-Silicon) and the like used for NVM devices. Further description of NVM and related technologies may be found at “Non Volatile Memory Technology”, 2005 published by Saifun Semiconductor; “Microchip Fabrication”, by Peter Van Zant, 5^{th} Edition 2004; “Application-Specific Integrated Circuits” by Michael John Sebastian Smith, 1997; “Semiconductor and Electronic Devices”, by Adir Bar-Lev, 2^{nd} Edition, 1999; “Digital Integrated Circuits” by Jan M. Rabaey, Anantha Chandrakasan and Borivoje Nikolic, 2^{nd} Edition, 2002 and materials presented at and through http://siliconnexus.com, “Design Considerations in Scaled SONOS Nonvolatile Memory Devices” found at:

http://klabs.org/richcontent/MemoryContent/nvmt_symp/nvmts_{—}2000/presentations/bu_white_sono s_lehigh_univ.pdf, “SONOS Nonvolatile Semiconductor Memories for Space and Military Applications” found at:

http://klabs.org/richcontent/MemoryContent/nvmt_symp/nvmts_{—}2000/papers/adams_d.pdf, “Philips Research—Technologies—Embedded Nonvolatile Memories” found at:

http://www.research.philips.com/tecinologies/ics/ivmemories/index.html, and “Semiconductor Memory: Non-Volatile Memory (NVM)” found at:

http://www.ece.nus.edu.sg/stfpage/elezhucx/myweb/NVM.pdf, all of which are incorporated by reference herein in their entirety.

### GLOSSARY

Unless otherwise noted, or as may be evident from the context of their usage, any terms, abbreviations, acronyms or scientific symbols and notations used herein are to be given their ordinary meaning in the technical discipline to which the disclosure most nearly pertains. The following terms, abbreviations and acronyms may be used throughout the descriptions presented herein and should generally be given the following meaning unless contradicted or elaborated upon by other descriptions set forth herein. Some of the terms set forth below may be registered trademarks (®).
anisotropic literally, one directional. An example of an anisotropic process is sunbathing. Only surfaces of the body exposed to the sun become tanned. (see “isotropic”).
array memory cells may optionally be organized in an array of rows and columns, and may be connected to selected bit lines and word lines in the array. The array may physically be divided into various sections, which may be referred to as:
   Array Area (AA)—memory cells, bit lines, word lines, contacts to bit lines and word lines
   Cell Area—portion of the Array Area which comprises memory cells
   Contact Area—a portion of the AA devoid of memory cells (and word lines) to allow for BL contacts
   Periphery Area—a portion of the memory chip, adjacent or surrounding the Array Area, comprising control circuitry, typically CMOS, for operating the Array
bit The word “bit” is a shortening of the words “binary digit.” A bit refers to a digit in the binary numeral system (base 2). A given bit is either a binary “1” or “0”. For example, the number 1001011 is 7 bits long. The unit is sometimes abbreviated to “b”. Terms for large quantities of bits can be formed using the standard range of prefixes, such as kilobit (Kbit), megabit (Mbit) and gigabit (Gbit). A typical unit of 8 bits is called a Byte, and the basic unit for 128 Bytes to 16K Bytes is treated as a “page”. That is the “mathematical” definition of “bit”. In some cases, the actual (physical) left and right charge storage areas of an NROM cell are conveniently referred to as the left “bit” and the right “bit”, even though they may store more than one binary bit (with MLC, each storage area can store at least two binary bits). The intended meaning of “bit” (mathematical or physical) should be apparent from the context in which it is used.
BL short for bit line. The bit line is a conductor connected to the drain (or source) of a memory cell transistor.
byte A byte is commonly used as a unit of storage measurement in computers, regardless of the type of data being stored. It is also one of the basic integral data types in many programming languages. A byte is a contiguous sequence of a fixed number of binary bits. In recent years, the use of a byte to mean 8 bits is nearly ubiquitous. The unit is sometimes abbreviated to “B”. Terms for large quantities of Bytes can be formed using the standard range of prefixes, for example, kilobyte (KB), megabyte (MB) and gigabyte (GB).
cap a term used to describe layers of a material disposed over another, dissimilar material, typically to protect the underlying material from damage during subsequent processing steps. A cap may be left in place, or removed, depending upon the situation.
Cell Well (CW) the cell well is an area in the silicon substrate that is prepared for functioning as a transistor or memory cell device by doping with an electron acceptor material such as boron or indium (p, electron acceptors or holes) or with an electron donor material such as phosphorous or arsenic (n, electron donors). The depth of a cell well is defined by the depth of the dopant distribution.
CMOS short for complementary metal oxide semiconductor. CMOS consists of n-channel and p-channel MOS transistors. Due to very low power consumption and dissipation as well as minimization of the current in “off” state, CMOS is a very effective device configuration for implementation of digital functions. CMOS is a key device in state-of-the-art silicon microelectronics.
   CMOS Inverter: A pair of two complementary transistors (a p-channel and an n-channel) with the source of the n-channel transistor connected to the drain of the p-channel transistor and the gates connected to each other. The output (drain of the p-channel transistor) is high whenever the input (gate) is low and the other way round. The CMOS inverter is the basic building block of CMOS digital circuits.
   NMOS: n-channel CMOS.
   PMOS: p-channel CMOS.
CMP short for chemical-mechanical polishing. CMP is a process, using both chemicals and abrasives, comparable to lapping, for removing material from a built up structure, resulting in a particularly planar resulting structure.
Dopant element introduced into semiconductor to establish either p-type (acceptors) or n-type (donors) conductivity; common dopants in silicon: p-type, boron, B, Indium, In; n-type phosphorous, P, arsenic, As, antimony, Sb.
EEPROM short for electrically erasable, programmable read only memory. EEPROMs have the advantage of being able to selectively erase any part of the chip without the need to erase the entire chip and without the need to remove the chip from the circuit. The minimum erase unit is 1 Byte and more typically a full Page. While an erase and rewrite of a location appears nearly instantaneous to the user, the write process is usually slightly slower than the read process; the chip can usually be read at full system speeds.
EPROM short for erasable, programmable read only memory. EPROM is a memory cell in which information (data) can be erased and replaced with new information (data).
Erase a method to erase data on a large set of bits in the array, such as by applying a voltage scheme that inject holes or remove electrons in the bit set. This method causes all bits to reach a low Vt level.
FET short for field effect transistor. The FET is a transistor that relies on an electric field to control the shape and hence the conductivity of a “channel” in a semiconductor material. FETs are sometimes used as voltage-controlled resistors. The terminals of FETs are called gate, drain and source.
isotropic literally, identical in all directions. An example of an isotropic process is dissolving a tablet in water. All exposed surfaces of the tablet are uniformly acted upon. (see “anisotropic”)
mask a layer of material which is applied over an underlying layer of material, and patterned to have openings, so that the underlying layer can be processed where there are openings. After processing the underlying layer, the mask may be removed. Common masking materials are photoresist and nitride. Nitride is usually considered to be a “hard mask”.
MOS short for metal oxide semiconductor.
MOSFET short for metal oxide semiconductor field-effect transistor. MOSFET is by far the most common field-effect transistor in both digital and analog circuits. The MOSFET is composed of a channel of n-type or p-type semiconductor material, and is accordingly called an NMOSFET or a PMOSFET. (The ‘metal’ in the name is an anachronism from early chips where gates were metal; modern chips use polysilicon gates, but are still called MOSFETs).
nitride commonly used to refer to silicon nitride (chemical formula Si3N4). A dielectric material commonly used in integrated circuit manufacturing. Forms an excellent mask (barrier) against oxidation of silicon (Si). Nitride is commonly used as a hard mask or, in the case of an NVM memory cell having an ONO layer as a charge-trapping material.
n-type semiconductor in which concentration of electrons is higher than the concentration of “holes”. See p-type.
NROM short for nitride read only memory.
NVM short for non-volatile memory. NVM is computer memory that can retain the stored information even when not powered. Examples of non-volatile memory include read-only memory, flash memory, most types of magnetic computer storage devices (for example hard disks, floppy disk drives, and magnetic tape), optical disc drives, and early computer storage methods such as paper tape and punch cards. Non-volatile memory is typically used for the task of secondary storage, or long-term persistent storage. The most widely used form of primary storage today is a volatile form of random access memory (RAM), meaning that when the computer is shut down, anything contained in RAM is lost. Unfortunately most forms of nonvolatile memory have limitations which make it unsuitable for use as primary storage. Typically non-volatile memory either costs more or performs worse than volatile random access memory. (By analogy, the simplest form of an NVM memory cell is a simple light switch. Indeed, such a switch can be set to one of two (binary) positions, and “memorize” that position.)
ONO short for oxide-nitride-oxide. ONO is used as a charge storage insulator consisting of a sandwich of thermally insulating oxide, and charge-trapping nitride.
oxide commonly used to refer to silicon dioxide (SiO2). Also known as silica. SiO2 is the most common insulator in semiconductor device technology, particularly in silicon MOS/CMOS where it is used as a gate dielectric (gate oxide); high quality films are obtained by thermal oxidation of silicon. Thermal SiO2 forms a smooth, low-defect interface with Si, and can be also readily deposited by CVD. Some particular applications of oxide are:
   LV Oxide short for low voltage oxide, LV refers to the process used to deposit the oxide.
   HV Oxide short for high voltage oxide. HV refers to the process used to deposit the oxide.
   STI Oxide short for shallow trench oxide. Oxide-filled trenches are commonly used to separate one region (or device) of a semiconductor substrate from another region (or device).
poly short for polycrystalline silicon (Si). Heavily doped poly Si is commonly used as a gate contact in silicon MOS and CMOS devices.
p-type semiconductor in which concentration of “holes” is higher than the concentration of electrons. See n-type. Examples of p-type silicon include silicon doped (enhanced) with boron (B), Indium (In) and the like.
resist short for photoresist, also abbreviated “PR”. Photoresist is often used as a masking material in photolithographic processes to reproduce either a positive or a negative image on a structure, prior to etching (removal of material which is not masked). PR is usually washed off after having served its purpose as a masking material
ROM short for read-only memory.
salicide The term salicide refers to a technology used in the microelectronics industry for the purpose of reducing the sheet resistance of the exposed silicon and poly-silicon areas. The salicide process involves the reaction of a thin metal film with silicon ultimately forming a metal silicide through a series of annealing and/or etch processes. The term “salicide” is a compaction of the phrase self-aligned silicide. The description “self-aligned” suggests that the silicide formation does not require lithographic patterning processes, as opposed to a non-aligned technology such as polycide. The term salicide is also used to refer to the metal silicide formed by the contact formation process, such as “titanium salicide”, although this usage is inconsistent with accepted naming conventions in chemistry. The salicide process may begin with deposition of a thin transition metal layer over fully formed and patterned semiconductor devices (such as transistors). The wafer is heated, allowing the transition metal to react with exposed silicon (such as source, drain, gate) forming a low-resistance transition metal silicide. The transition metal does not react with the silicon oxide and or nitride insulators present on the wafer. Following the reaction, any remaining transition metal is removed by chemical etching, leaving silicided silicon. The silicided silicon is then further heat treated to font a lower resistance silicide
sector a part of the array, usually larger than a page, which usually contains a few pages. A minimum erase might include a sector.
self-aligned In fabrication of MOSFETs on integrated circuits, a self-aligned gate is an arrangement where the edges of the source and drain doping regions next to the gate are defined by the same mask that defines the edges of the gate next to the source and drain regions. An overlap between the source, drain and gate regions would be difficult to achieve without the self-aligned feature (due to the inherent misalignment between different masking layers). “Self-aligned” may also refer to any process step where a previously-formed structure acts as a mask for a subsequent process step, such as deposition or etching.
Si Silicon, a semiconductor.
SONOS Si-Oxide-Nitride-Oxide-Si, another way to describe ONO with the Si underneath and the Poly gate on top.
spacer a spacer, as the name implies, is a material (such as a layer of oxide) disposed on an element (such as a poly gate electrode). For example, sidewall spacers disposed on opposite sides of a gate electrode structure cause subsequent implants to occur further away from the gate than otherwise (without the spacers in place), thereby controlling (increasing) the length of a channel under the gate electrode structure.
Units of Length Various units of length may be used herein, as follows:
   meter (m) A meter is the SI unit of length, slightly longer than a yard. 1 meter=˜39 inches. 1 kilometer (km)=1000 meters=˜0.6 miles. 1,000,000 microns=1 meter. 1,000 millimeters (mm)=1 meter. 100 centimeters (cm)=1 meter.
   micron (μm) one millionth of a meter (0.000001 meter); also referred to as a micrometer.
   mil 1/1000 or 0.001 of an inch; 1 mil=25.4 microns.
   nanometer (nm) one billionth of a meter (0.000000001 meter).
   Angstrom (Å) one tenth of a billionth of a meter. 10 Å=1 nm.
word line or wordline, (WL). A conductor normally connected to the gate of a memory cell transistor. The wordline may actually be the gate electrode of the memory cell.

In addition to the above, some abbreviations that may be used herein, or in a provisional application from which this non-provisional application claims priority, include:
Active Area—the area outside the STI (or field area).
BB short for buried bitline.
BL short for bitline.
CESL short for Contact Etch Stop Layer.
CT short for contact.
DEP short for deposition.
ILD short for inter-layer dielectric
Ld Ld is a term given to a minimal geometry feature supported by the technology.
SAC short for self-aligned contact.
STI short for silicon trench isolation.

### BRIEF DESCRIPTION (SUMMARY)

Generally, techniques for forming buried contact etch stop layers (CESL) between adjacent diffusions and that are self-aligned to these adjacent diffusions in a semiconductor device are disclosed. The diffusions include, but are not limited to, silicides, metals, raised or buried diffusions. The CESL may comprise nitride or any other material that is harder (more resistant) to etch than the material on top of it. The diffusions between which the CESL is disposed include, but are not limited to, bitlines and the semiconductor devices include, but are not limited to, memory arrays.

According to an embodiment of the disclosure, a semiconductor device comprises: spaced-apart diffusions; and a buried contact etch stop layer (CESL) between adjacent diffusions. The diffusions may comprise bitlines; and the semiconductor device may comprise a memory array. The CESL may comprise nitride, or another material that is harder (more resistant) to etch than a material on top of the CESL. The material on top of the CESL may be inter-level dielectric (ILD). The semiconductor device may comprise a non-volatile memory (NVM) device, which may be selected from the group consisting of NROM, SONOS, SANOS, MANOS, TANOS and Floating Gate (FG) devices. The CESL may be self-aligned to the diffusions. The CESL may be completely enclosed within oxide. The CESL may be bounded on all sides by oxide and/or polysilicon. Shallow trench isolation (STI) may be formed under the CESL. The CESL may be formed by an oxide/CESL dep-etch-dep process, and may be configured from a hard mask.

According to an embodiment of the disclosure, an array of memory cells comprises: a plurality of bitlines extending through a contact area in the array; memory devices connected between the bitlines in a cell area adjacent to the contact area; and a buried contact etch stop layer (CESL) between adjacent bitlines. The bitlines may include, but are not limited to, silicides, metals, raised or buried bitlines. Oxide may be disposed under the buried CESL and may surround at least a portion of the buried CESL. Polysilicon may be disposed under the buried CESL and may surround at least a portion of the buried CESL. Bitline oxide may be disposed over the buried CESL. STI trenches may be disposed between the bitlines. The memory cells may comprise NVM devices selected from the group consisting of NROM, SONOS, SANOS, MANOS, TANOS and Floating Gate (FG) devices.

Generally, the purpose of the CESL in a memory array disclosed herein is to prevent misaligned bitline (BL) contacts from contacting silicon outside of the corresponding bitlines.

Advantages of the techniques for forming buried CESL in a memory array disclosed herein include, but are not limited to:
the CESL is self-aligned to the bitline
there is no need to form STI trenches
the bit line contact, if misaligned, will not contact the underlying silicon
The contact to the bitlines may, optionally, be made larger to overlap the self aligned CESL thereby ensuring full coverage of the contact by the bitlines.
Full coverage of the contacts by the bitlines may, if necessary, eliminate the use of an additional mask to implant into the contacts.

The techniques disclosed herein may be applicable to most semiconductor devices including, but not limited to, NVM devices, including, but not limited to, NROM (sometimes referred to as Nitride Read Only Memory), SONOS (Semiconductor Oxide Nitride Oxide Semiconductor; Silicon-Oxide-Nitride-Oxide-Silicon), SANOS (Silicon-Aluminum Oxide-Nitride-Oxide-Silicon), MANOS (Metal-Aluminum Oxide-Nitride-Oxide-Silicon), TANOS (Tantalum-Aluminum Oxide-Nitride-Oxide-Silicon) and Floating Gate (FG) devices.

### BRIEF DESCRIPTION OF THE DRAWING(S)

Reference will be made in detail to embodiments of the disclosure, examples of which may be illustrated in the accompanying drawing figures (FIGs). The figures are intended to be illustrative, not limiting. Although the disclosure is generally described in the context of these embodiments, it should be understood that it is not intended to limit the disclosure to these particular embodiments.

Certain elements in selected ones of the figures may be illustrated not-to-scale, for illustrative clarity. The cross-sectional views, if any, presented herein may be in the form of “slices”, or “near-sighted” cross-sectional views, omitting certain background lines which would otherwise be visible in a true cross-sectional view, for illustrative clarity. In some cases, hidden lines may be drawn as dashed lines (this is conventional), but in other cases they may be drawn as solid lines.

If shading or cross-hatching is used, it is intended to be of use in distinguishing one element from another (such as a cross-hatched element from a neighboring un-shaded element). It should be understood that it is not intended to limit the disclosure due to shading or cross-hatching in the drawing figures.

Elements of the figures may (or may not) be numbered as follows. The most significant digits (hundreds) of the reference number correspond to the figure number. For example, elements of FIG. 1 are typically numbered in the range of 100-199, and elements of FIG. 2 are typically numbered in the range of 200-299. Similar elements throughout the figures may be referred to by similar reference numerals. For example, the element 199 in FIG. 1 may be similar (and possibly identical) to the element 299 in FIG. 2. Throughout the figures, each of a plurality of elements 199 may be referred to individually as 199a, 199b, 199c, etc. Such relationships, if any, between similar elements in the same or different figures will become apparent throughout the specification, including, if applicable, in the claims and abstract.

Throughout the descriptions set forth in this disclosure, lowercase numbers or letters may be used, instead of subscripts. For example Vg could be written V_{g}. Generally, lowercase is preferred to maintain uniform font size. Regarding the use of subscripts (in the drawings, as well as throughout the text of this document), sometimes a character (letter or numeral) is written as a subscript-smaller, and lower than the character (typically a letter) preceding it, such as “Vₛ” (source voltage) or “H₂O” (water). For consistency of font size, such acronyms may be written in regular font, without subscripting, using uppercase and lowercase—for example “Vs” and “H2O”.

Conventional electronic components may be labeled with conventional schematic-style references comprising a letter (such as A, C, Q, R) indicating the type of electronic component (such as amplifier, capacitor, transistor, resistor, respectively) followed by a number indicating the iteration of that element (such as “1” meaning a first of typically several of a given type of electronic component). Components such as resistors and capacitors typically have two terminals, which may be referred to herein as “ends”. In some instances, “signals” are referred to, and reference numerals may point to lines that carry said signals. In the schematic diagrams, the various electronic components are connected to one another, as shown. Usually, lines in a schematic diagram which cross over one another and where there is a dot at the intersection of the two lines are connected with one another, else (if there is no dot at the intersection) they are typically not connected with one another.

FIG. 1 is a stylized cross-sectional view of a field effect transistor (FET), according to the prior art. To the left of the figure is a schematic symbol for the FET.

FIG. 2 is a stylized cross-sectional view of a floating gate memory cell, according to the prior art. To the left of the figure is a schematic symbol for the floating gate memory cell.

FIG. 3 is a stylized cross-sectional view of a two bit NROM memory cell of the prior art. To the left of the figure is a schematic symbol for the NROM memory cell.

FIG. 4 is a diagram of a memory cell array with NROM memory cells, according to the prior art.

FIG. 4A is a plan view of a memory chip, according to the prior art.

FIG. 5 is a diagram of a contact region in a memory array, such as may be formed according to this disclosure.

FIG. 6 is a cross-sectional view of a memory array (or a portion thereof) illustrating a first step of an overall process of forming a memory array, according to an embodiment of this disclosure.

FIGS. 7-11 are cross-sectional views of subsequent steps of the overall process of forming a memory array, according to this disclosure.

FIG. 12 is a plan view of the memory array (or a portion thereof) illustrating a subsequent step of the overall process of forming a memory array, according to this disclosure.

FIG. 13 is a plan view of the memory array (or a portion thereof) illustrating a subsequent step of the overall process of forming a memory array, according to this disclosure.

FIG. 14 is a plan view of the memory array (or a portion thereof) illustrating a subsequent step of the overall process of forming a memory array, according to this disclosure.

FIGS. 15A, 15B and 15C are cross-sectional views of a subsequent step of the overall process of forming a memory array, according to this disclosure.

FIG. 16 is a plan view of the memory array (or a portion thereof) illustrating a subsequent step of the overall process of forming a memory array, according to this disclosure.

FIGS. 17A, 17B and 17C through FIGS. 22A, 22B and 22C are cross-sectional views of a subsequent step of the overall process of forming a memory array, according to this disclosure. The “A”, “B” and “C” views are generally different sections taken through lines X-X, Y-Y and Z-Z, respectively, through FIG. 16.

FIG. 23 is a cross-sectional view of a subsequent step of the overall process of forming a memory array, according to this disclosure.

FIG. 24 is a cross-sectional view of a memory array (or a portion thereof) illustrating a first step of an alternate embodiment of an overall process of forming a memory array, according to an embodiment of this disclosure.

FIG. 25 is a plan view of the memory array (or a portion thereof) illustrating a subsequent step of the overall process of forming a memory array, according to this disclosure.

FIG. 26 is a plan view of the memory array (or a portion thereof) illustrating a subsequent step of the overall process of forming a memory array, according to this disclosure.

FIGS. 27A and 27B are cross-sectional views of the memory array (or a portion thereof) illustrating alternate embodiments of a subsequent step of the overall process of forming a memory array, according to this disclosure.

FIG. 28 is a plan view of the memory array (or a portion thereof illustrating a subsequent step of the overall process of forming a memory array, according to this disclosure.

FIGS. 29A, 29B and 29C are cross-sectional views of a subsequent step of the overall process of forming a memory array, according to this disclosure. The “A”, “B” and “C” views are generally different sections taken through lines X-X, Y-Y and Z-Z, respectively, through FIG. 28.

FIG. 30 is a plan view of the memory array (or a portion thereof) illustrating a subsequent step of the overall process of forming a memory array, according to this disclosure.

FIG. 31 is a cross-sectional view of the memory array (or a portion thereof) illustrating a subsequent step of the overall process of forming a memory array, according to this disclosure.

FIGS. 32A, 32B and 32C are cross-sectional views of a subsequent step of the overall process of forming a memory array, according to this disclosure. The “A”, “B” and “C” views are generally different sections taken through lines X-X, Y-Y and Z-Z, respectively, through FIG. 28.

FIG. 33 is a plan view of the memory array (or a portion thereof) illustrating a subsequent step of the overall process of forming a memory array, according to this disclosure.

FIGS. 34A, 34B and 34C through FIGS. 36A, 36B and 36C are cross-sectional views of a subsequent step of the overall process of forming a memory array, according to this disclosure. The “A”, “B” and “C” views are generally different sections taken through lines X-X, Y-Y and Z-Z, respectively, through FIG. 33.

FIG. 37 is a plan view of the memory array (or a portion thereof) illustrating a subsequent step of the overall process of forming a memory array, according to this disclosure.

FIGS. 38A, 38B and 38C through FIGS. 43A, 43B and 43C are cross-sectional views of a subsequent step of the overall process of forming a memory array, according to this disclosure. The “A”, “B” and “C” views are generally different sections taken through lines X-X, Y-Y and Z-Z, respectively, through FIG. 37.

FIG. 44 is a cross-sectional view of a subsequent step of the overall process of forming a memory array, according to this disclosure.

### DETAILED DESCRIPTION

The disclosure is generally directed to techniques for forming a self-aligned buried contact etch stop layer (CESL) between adjacent diffusions in a semiconductor device. The diffusions include, but are not limited to, silicides, metals, raised or buried diffusions. For convenience and clarity of presentation, the diffusions in the exemplary embodiments are bitlines (BL) and the semiconductor device is a memory array.

Two exemplary embodiments are disclosed. It should be understood that various process steps both before and after CESL formation (and filling) are disclosed, in order to provide a context for the embodiments discussed herein, and these additional pre- and post-CESL process steps should not be interpreted as limiting the disclosure to the specific examples which are discussed.

For example, the process of forming buried CESL is described in greater detail hereinbelow in the context of a “dual poly process” (DPP) for forming memory arrays with buried bitlines (BBs), wherein a first poly (Poly-1) deposited on ONO delineates the bit lines. Generally, in DPP, oxide deposited over the bit lines is planarized, and a second poly (Poly-2) patterned along with the underlying Poly-1 defines the word lines.

### AN EMBODIMENT OF A BURIED CESL PROCESS

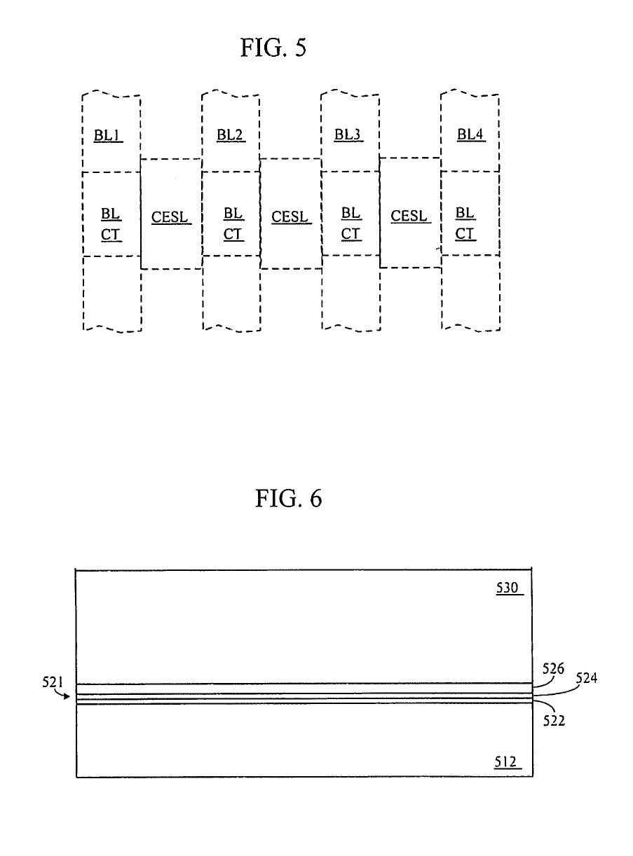

FIG. 5 illustrates, generally, a contact region in a memory array comprising a plurality (four shown) of bitlines (labeled BL1 . . . BL4) extending vertically and spaced horizontally from one another. By way of example, the bitlines may each have a width (in the horizontal direction) of 60 nm, and may be spaced 100 nm apart from one another.

A bitline contact (BLCT) will extend through inter-layer dielectric (ILD, not shown, described hereinbelow) to each of the bitlines BL1 . . . BL4, and may all be at a given, uniform vertical position on the bitline, as illustrated. The bitline contacts BLCT may have an exemplary same width (horizontal dimension) as the bitlines BL1 . . . BL4—for example, 60 nm. Optionally, the widths may be made larger to overlap the self aligned CESL thereby ensuring full coverage of the contact by the bitlines. The full coverage of the contacts by the bitlines may, if necessary, eliminate the use of an additional mask to implant into the contacts. The vertical extent of the bitline contacts may, if necessary, be made larger as, for example, 90 nm.

The vertical extent of the contact region is generally determined by an array uniformity requirement. Optionally, two wordlines may be removed to allow for the contact placement, and the vertical dimension is established accordingly.

In case a bitline contact is misaligned (horizontally) with the corresponding bitline, it may extend over silicon between the bitlines, which is not desirable, since that may cause leakage (bitline-to-bitline leakage). Since the bitline contacts are not self-aligned, in case there is a mask alignment deviation, many bitline contacts may be misaligned with their corresponding bitlines. One known option is to provide silicon-trench isolation (STI) between the bitlines, in the contact region, so that misaligned portions of bitline contact(s) will “land” on insulator, without causing bitline-to-bitline leakage.

According to this (and the next) embodiment of the disclosure, STI need not be formed. Rather, a buried contact etch stop layer (CESL) may be provided to prevent problems resulting from contact misalignment.

Typically, the bit line width is less than or equal to the minimum allowable (process & photolithography wise) contact width.

FIG. 5 illustrates that a contact etch stop layer (CESL) may be formed between each of the adjacent bitlines, such as between BL1 and BL2, between BL2 and BL3, and between BL3 and BL4. The CESL may be a nitride structure (an insulating material) disposed between the adjacent bitlines. The CESL may, optionally, have nearly the same width (horizontal dimension) as the spacing between the bitlines, and is at substantially the same vertical position as the bitline contacts, and should extend vertically beyond the bitline contacts to ensure that any misaligned portion of a bitline contact will “land” on CESL, rather than on silicon, thereby maintaining isolation of adjacent bitlines. The CESL may extend to nearly the full width of the contact region.

In FIG. 5, the bitlines, bitline contacts and CESL are shown in dashed lines, since they are not yet formed. This figure simply represents, at the “Active Mask” level, the general layout of these elements in the contact region.

FIG. 6 illustrates a first step (Deposit ONO and Poly-1) in the overall process of forming a memory array, with Self-aligned Buried CESL bordered Array Contacts (or “bitline contacts”, BLCT).

An ONO stack 521 (compare 321) comprising a bottom (lower) oxide layer 522 (compare 322), a layer 524 (compare 324) of charge-trapping material such as nitride, and a top (upper) oxide layer 526 (compare 326) is deposited on a substrate 512 (compare 312). The ONO stack 521 may have an overall thickness of approximately 10-50 nm, such as 18 nm, as follows:
the bottom oxide layer 522 may be from 3 to 10 nm, for example 4 nm thick;
the middle nitride layer 524 may be from 3 to 12 nm, for example 4 nm thick; and
the top oxide layer 526 may be from 5 to 25 nm, for example 10 nm thick.

Optionally ONO 512 may be etched (removed) from the periphery (CMOS) area (not shown, compare 454). Generally, ONO 521 will cover the array.

A first layer 530 of polysilicon (“poly”; “Poly-1”) may be deposited, to a thickness of approximately 10-250 nm, such as 70 nm, over the ONO 521.

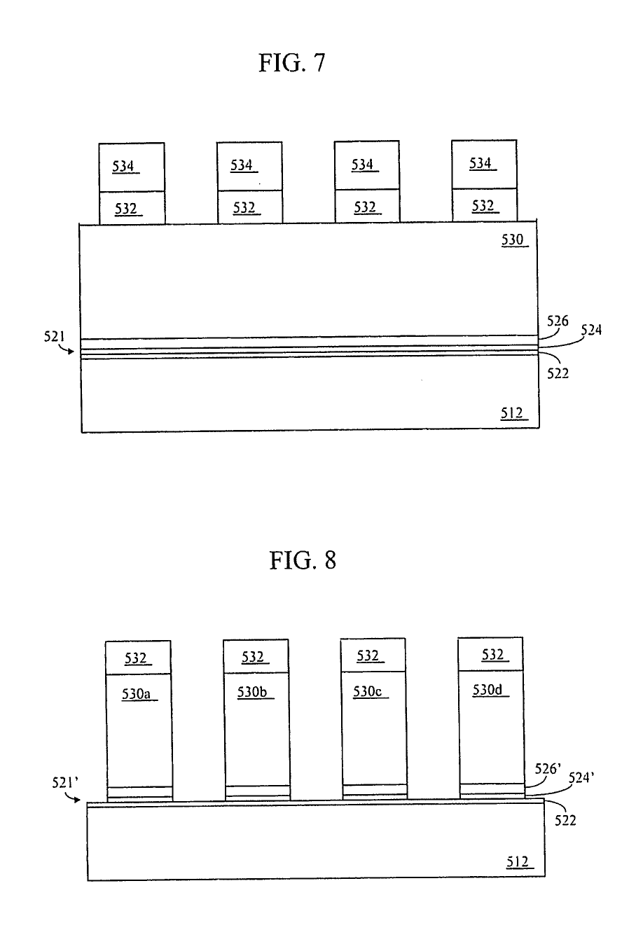

FIG. 7 illustrates a next step (Poly-1 Array Mask) in the overall process of forming a memory array, with Self-aligned Buried CESL bordered Array Contacts. A layer of nitride 532 is deposited over the poly 530, photoresist 534 is deposited and patterned (over the nitride 532), the nitride 532 is etched to form a hard mask 532, and the resist 534 is removed (stripped not shown), leaving the nitride hard mask 532.

FIG. 8 illustrates a next step (Etch Poly-1 and ONO) in the overall process of forming a memory array, with Self-aligned Buried CESL bordered Array Contacts. The poly 530 (Poly-1) is etched, using the nitride hard mask 532 stopping on the top oxide 526 of the ONO stack 521. This results in individual poly structures (or “lines”) 530a, 530b, 530c and 530d (which may generally be referred to as “530”), as shown, each of which has underneath it a segment of the original ONO stack 521 (now labeled 521′ (prime)), wherein the top oxide layer is labeled 526′ (prime), and the nitride layer is labeled 524′ (prime). The Poly-1 structures 530 may have an exemplary width of 100 nm, an exemplary height of 50 nm, and may be spaced 60 nm apart from one another.

Then, the top oxide 526 and nitride 524 of the ONO stack 521 are etched, in the spaces (gaps) between the Poly-1 structures 530, stopping on the bottom oxide 522. The original bottom oxide layer 522, now exposed between the poly structures 530, may be unaffected.

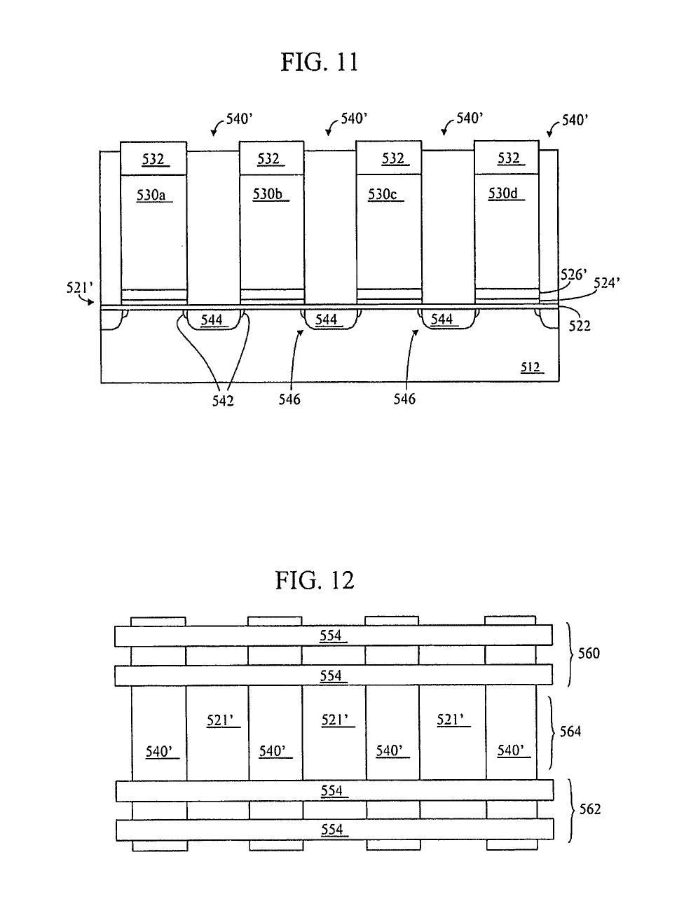

The nitride 532, now thinned, may be left in place to act as an etch stop for a subsequent CMP process (see FIG. 11).

A reason for leaving the bottom oxide 522 in place is to protect the underlying silicon 512. Optionally, a thin layer of oxide (not shown) may be grown to protect exposed silicon and “heal” the etch damage.

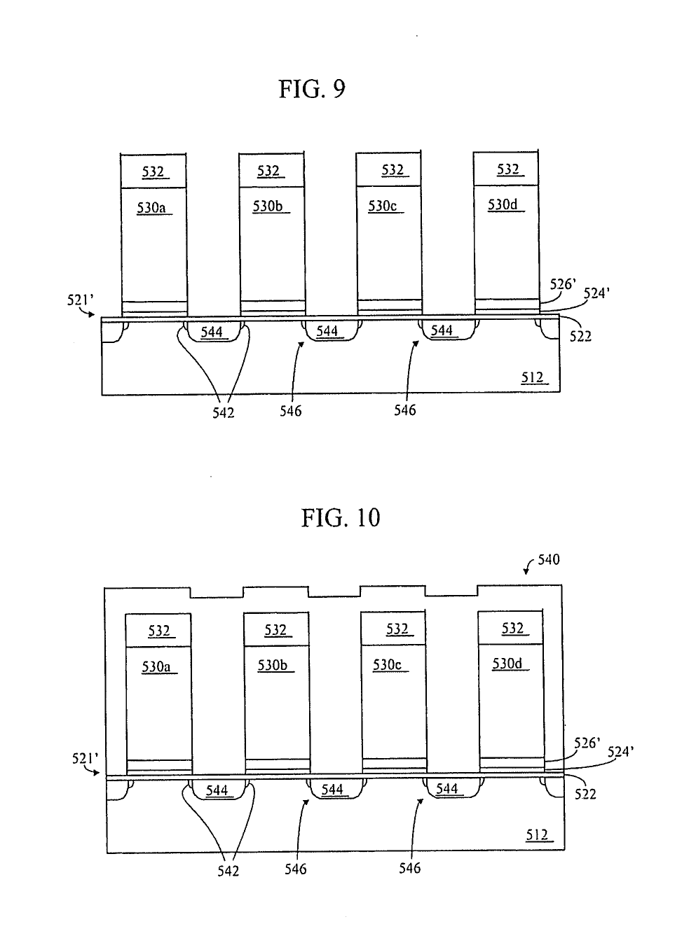

FIG. 9 illustrates a next step (Bit Line Implant) in the overall process of forming a memory array, with Self-aligned Buried CESL bordered Array Contacts. A pocket implant 542 may optionally be formed, followed by a bit line implant 544. Some exemplary process parameters are:
for the pocket implant 542, 0.5-6×10¹³/cm2 (dose of the dopant per unit area) and energy of 10-20 Kev, no tilt, boron (B), although the scope of the disclosure is not limited in this respect.
for the bitline implant 544, 1.0-1.5E¹⁵ cm2, 10-20 Kev, Arsenic (As), through the ONO Bottom Oxide, although the scope of the disclosure is not limited in this respect.

The resulting “buried bitline” 546, comprising pocket implant 542 and 544 is situated substantially in the space between adjacent poly structures 530, and extends into the surface of the silicon 512, to an exemplary depth in the range of 10 nm-500 nm, such as 50 nm. These buried bitlines 546 will act as source and drain diffusions (compare 314 and 316) of memory cells, and the poly lines 530 will function as the gate (compare 328) of the memory cells.

In subsequent figures, the buried bitline (BB) 546 may be shown without the pocket implant 542, for illustrative clarity.

FIG. 10 illustrates a next step (Oxide Deposition and Fill) in the overall process of forming a memory array, with Self-aligned Buried CESL bordered Array Contacts. Oxide 540 is deposited, filling, and overfilling the gaps between adjacent poly lines 530.

FIG. 11 illustrates a next step (Oxide CMP) in the overall process of forming a self-aligned buried contact etch stop layer (CESL). Excess oxide 540 overfilling the gaps between adjacent poly lines 530 is removed, using a chemical mechanical polishing (CMP) process. Note that the nitride hard mask 532 is still in place. The resulting oxide is labeled 540′ (prime). Here it can be seen that the nitride 532, which polishes at a much slower rate than oxide, is useful as a CMP etch stop.

The oxide 540′ remaining between adjacent poly lines 530 is directly over the corresponding silicides, metals, raised or buried bitlines 546, and may be referred to as “bitline oxide”.

Eventually, as will be described hereinbelow, openings will be made through these bitline oxides, and filled with a conductor (such as metal), to form bitline contacts in the contact region of the memory array.

FIG. 12 illustrates the array near the contact area after the word lines 554 have been formed (Array Contact Area after Poly-2 Word Line Etch), in the overall process of forming a memory array, with Buried CESL bordered Array Contacts. As illustrated in this figure, two (of many) word lines will be formed in a first group 560 of word lines 554, and are separated from two (of many) word lines 554 which are in a second group 562 of word lines 554. A contact region 564 is disposed between the first and second groups of wordlines, and is representative of any number of contact regions which may be disposed throughout the memory array.

In FIGS. 11 and 12, it can be seen that there are a number of buried bitlines (compare FIG. 9) running vertically in the array, and these buried bitlines are covered by bitline oxide 540′ (“oxide pillars”). Between the oxide pillars 540′ is “residual” ONO 521′, and this is generally where the buried contact etch stop layer (CESL) will be formed. The bitlines 546 extend (or pass) through the contact area 564 and into the cell areas 560 and 562 of the array.

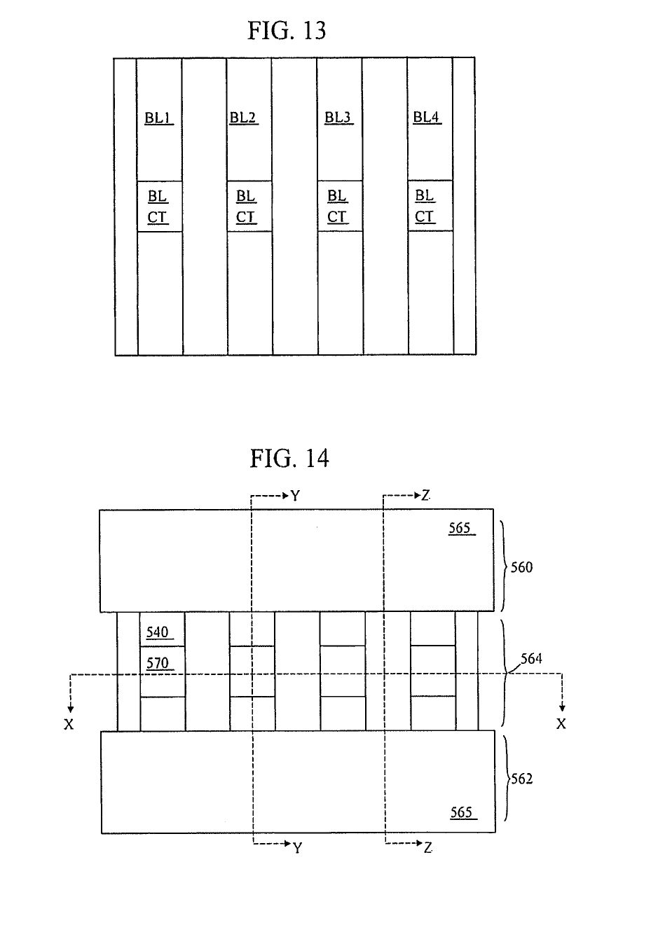

FIG. 13 illustrates a next step (BL Contacts Area after Oxide CMP) in the overall process of forming a self-aligned buried contact etch stop layer (CESL). This is generally simply a top plan view of the interim product shown in the cross-section of FIG. 12. The figure shows where the bitline contacts (BLCT) are intended to be formed.

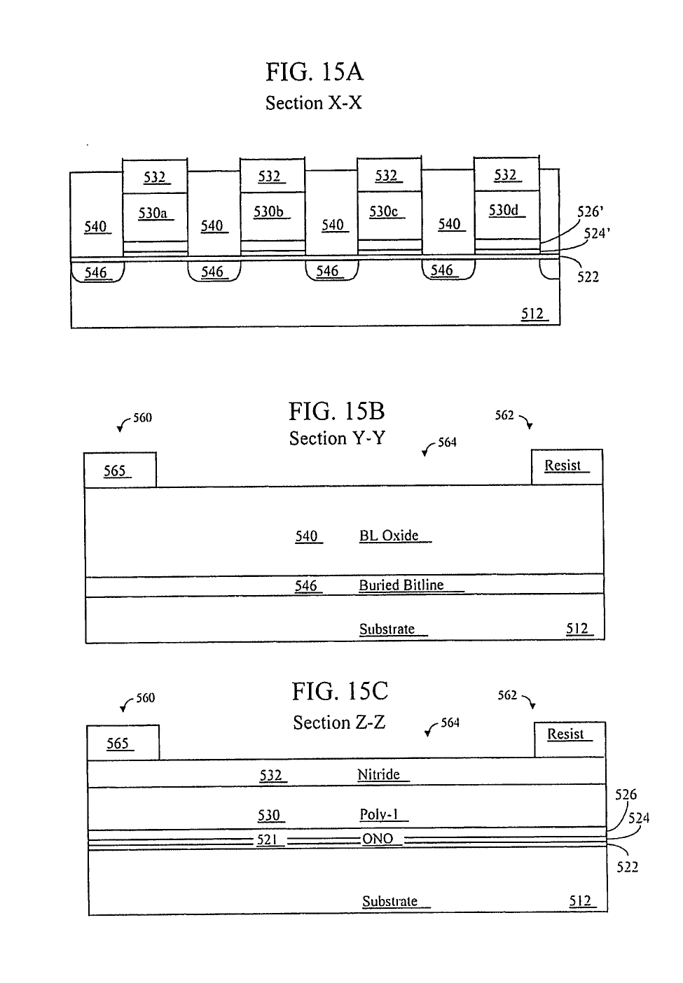

FIG. 14 illustrates a next step (BL Contacts Area Mask) in the overall process of forming a self-aligned buried contact etch stop layer (CESL).

Note the section lines X-X, Y-Y and Z-Z. In this, and in some subsequent figures:
X-X cross-sections are taken through the contact area 564, at a position where the bitline contacts BLCT 570, described hereinbelow, will be formed.
Y-Y cross-sections are taken through the array, along a bitline (BL) 546, and traverse the contact area 564 into the wordline areas 560 and 562 adjacent the contact area 564.
Z-Z cross-sections are taken through the array, between bitlines (BL) 546, and traverse the contact area 564 into the wordline areas 560 and 562 adjacent the contact area 564.

In FIG. 14, and subsequent figures, the reference numeral 540 is used to indicate the bitline oxide, which may have been planarized (CMP), rather than using the prime version (540′), for illustrative clarity. The same (reverting to non-prime nomenclature) may be true for other elements, such as ONO 521, for illustrative clarity.

Photoresist (“Resist”) 565 is shown covering (masking) the wordline areas 560 and 562, leaving the contact area 564 exposed, for further processing.

FIG. 15A is a cross-sectional view on a line X-X through the view of FIG. 14, in the overall process of forming a self-aligned buried contact etch stop layer (CESL). This is similar to FIG. 11.

Note that the bottom oxide 522 (residual ONO) atop the buried bitline (BB) 546 is covered by bitline oxide (BL Oxide) 540.

FIG. 15B is a cross-sectional view on a line Y-Y through the view of FIG. 14, in the overall process of forming a self-aligned buried contact etch stop layer (CESL).

In FIG. 15B, the resist mask 565 can be seen covering portions of the BL Oxide 540 in the wordline areas (560, 562), leaving the contact area 564 exposed.

FIG. 15C is a cross-sectional view on a line Z-Z through the view of FIG. 14, in the overall process of forming a self-aligned buried contact etch stop layer (CESL).

In FIG. 15C, the resist mask 565 can be seen covering portions of the nitride 532 in the wordline areas (560, 562), leaving the contact area 564 exposed.

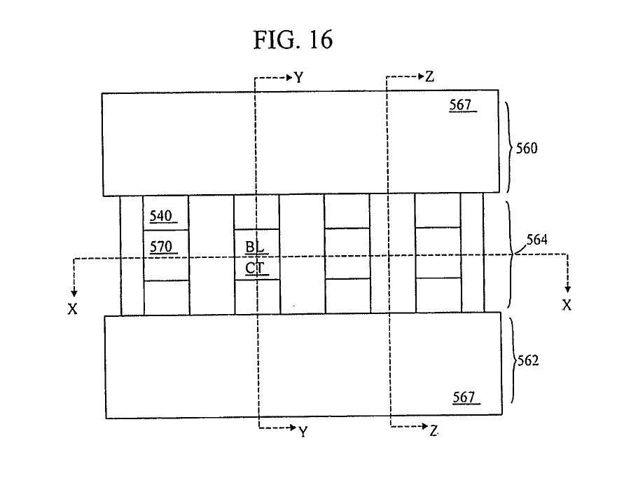

FIG. 16 is a plan view of a next step (BL Contacts Area Mask) in the overall process of forming a self-aligned buried contact etch stop layer (CESL). Note the section lines X-X, Y-Y and Z-Z.

Photoresist (“Resist”) 567 is shown covering (masking) the wordline areas 560 and 562, leaving the contact area 564 exposed. (Generally, the coverage of the mask 567 in FIG. 16 is the same as the coverage of the mask 565 in FIG. 14.)

The Nitride and Poly in the exposed contact area are now etched. (Dry Nitride Etch followed by Dry Poly Etch).

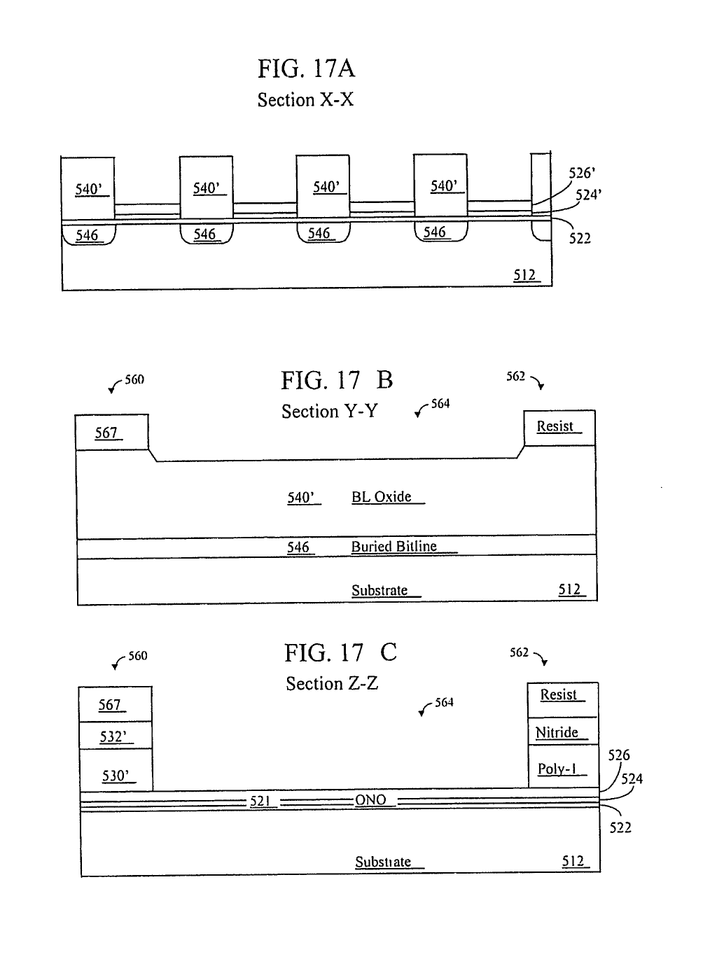

As shown in the next step (refer to FIG. 17A), with the mask 567 in place, a dry nitride etch is performed. Also, Poly-1 530 is etched, stopping on ONO 521 in the contact area. During these etch steps, the thickness of the BL Oxide 540 may be reduced.

FIG. 17A is a cross-sectional view on a line X-X through the view of FIG. 14, and illustrates a next step (Dry Etch Nitride/Poly in Contact Area) in the overall process of forming a self-aligned buried contact etch stop layer (CESL).

In FIG. 17A (comparing with FIG. 15A), it can be seen that nitride 532 and poly 530 have been removed between the BL oxides 540, and the BL oxides 540′ (prime) have become thinned. (Here, the prime version of 540 is used to show that the bitline oxide was modified since the previous step. In subsequent figures, the non-prime version may again be used.)

FIG. 17B is a cross-sectional view on a line Y-Y through the view of FIG. 16, and illustrates a next step (Dry Etch Nitride/Poly in Contact Area) in the overall process of forming a self-aligned buried contact etch stop layer (CESL).

In FIG. 17B, the thinning of the bitline oxide 540′ (prime) from the nitride dry etch is apparent.

FIG. 17C is a cross-sectional view on a line Z-Z through the view of FIG. 16, and illustrates a next step (Dry Etch Nitride/Poly in Contact Area) in the overall process of forming a self-aligned buried contact etch stop layer (CESL).

In FIG. 17C, it can be observed that the poly (Poly-1) 530′ (prime) has been patterned, as well as the nitride hard mask (HM) 532′ (prime) atop Poly-1 530′ and that the nitride (532′) and the poly (530′) in the contact area have been etched.

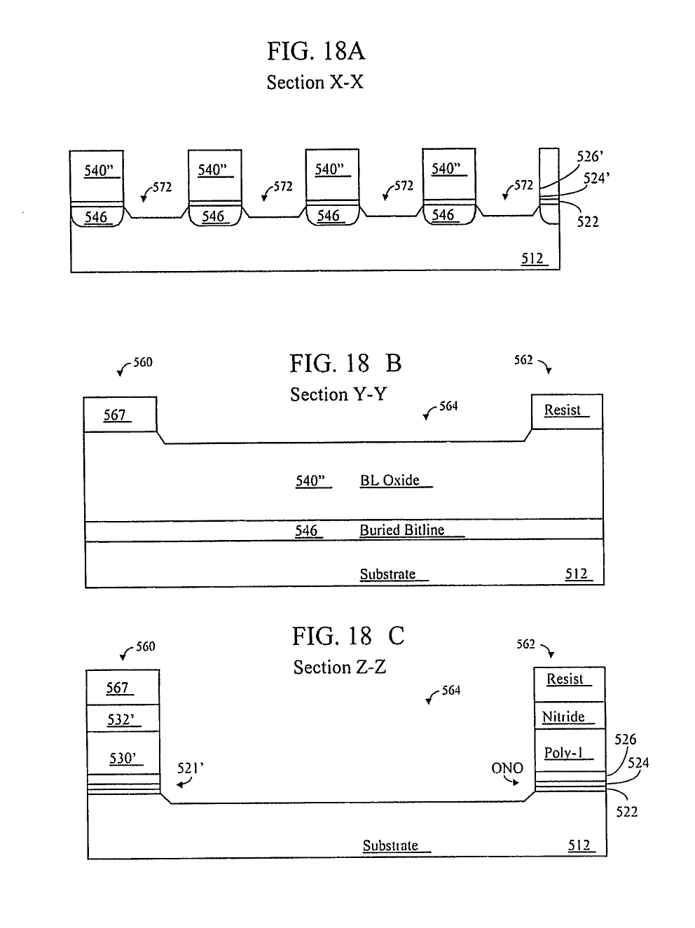

FIGS. 18A, 18B and 18C illustrate an optional step that may be performed at this time.

FIG. 18A is a cross-sectional view on a line X-X through the view of FIG. 16, and illustrates an optional next step (Shallow STI aligned to BL oxide) in the overall process of forming a self-aligned buried contact etch stop layer (CESL).

Forming shallow silicon trench isolation (STI) is optional, and may proceed as follows:
First, etch residual ONO 521′ from between BL Oxide Pillars 540′. In the process, the BL oxide will get thinned, and is thus shown in this figure with double-prime, as 540″.
Next etch the silicon 512 to form a shallow trench 572 between the BL Oxide Pillars 540″.
Next, perform an implant (not shown), if necessary.
The trenches 572 will be filled (with oxide), in the next step.

Generally, the purpose of performing a shallow STI etch is to ensure that there is good isolation between bitlines, particularly in cases where the aspect ratio (height to separation) of the bitline oxides is not conducive to a good gap fill (in the next step).

FIG. 18B is a cross-sectional view on a line Y-Y through the view of FIG. 16, and illustrates the same optional step as FIG. 18A (Shallow STI aligned to BL oxide) in the overall process of forming a self-aligned buried contact etch stop layer (CESL).

Generally, except for a further thinning of the BL oxide due the ONO etch there has been no change from the previous step shown in FIG. 17B.

FIG. 18C is a cross-sectional view on a line Z-Z through the view of FIG. 16, and illustrates the same optional step as FIG. 18A (Shallow STI aligned to BL oxide) in the overall process of forming a self-aligned buried contact etch stop layer (CESL). Here it can be seen that the ONO 521 is stripped and a trench is formed in the exposed surface of the substrate 512.

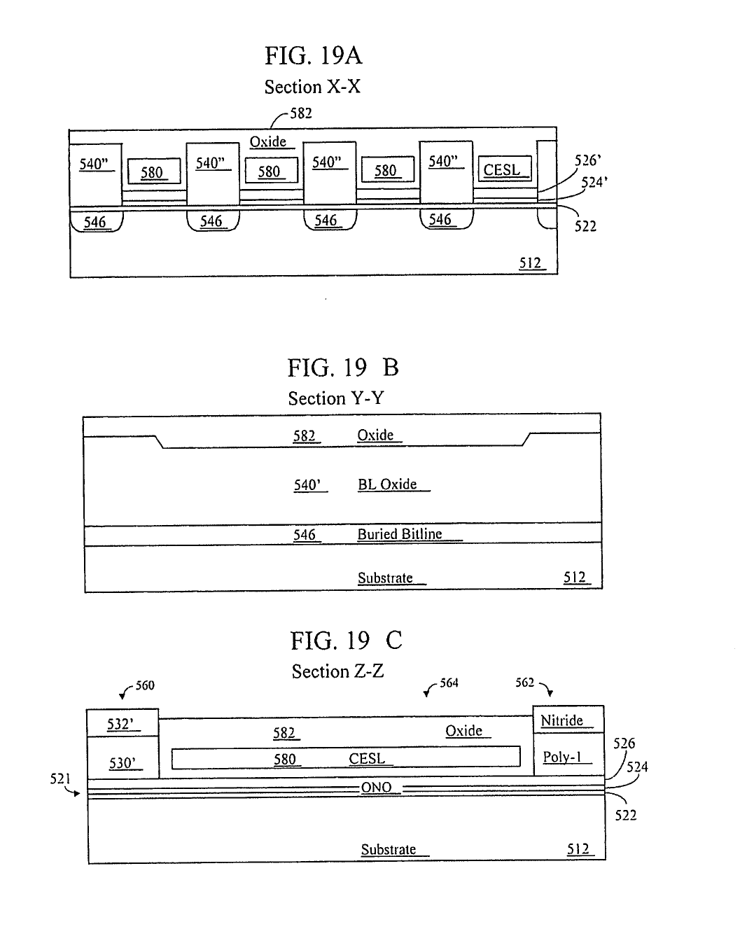

FIG. 19A is a cross-sectional view on a line X-X through the view of FIG. 16, and illustrates a next step (Buried CESL Fill) in the overall process of forming a self-aligned buried contact etch stop layer (CESL).

Generally, this step is being described without the optional shallow STI step described in FIGS. 18A-18C.

First, the resist 567 is stripped. Then the following “dep-etch-dep” steps are performed, and may optionally be performed “in situ” (generally meaning, in the same apparatus without removing the wafer).

Oxide may be deposited and etched, followed by a contact etch stop material such as nitride being deposited and etched, followed by another oxide deposit (and CMP).

The resulting structure is shown as a CESL layer 580, surrounded by oxide 582 on all four sides (top, bottom, left and right, as viewed), and disposed between the bitline oxides 540″, above the top oxide 526 of the ONO 521 stack, and below the top surface of the bitline oxides 540″.

Alternatively, the CESL, layer 580 can extend completely to the bitline oxides 540″.

Alternatively, the CESL layer 580 can sit directly on the top oxide 526 of the ONO 521 stack.

Alternatively, the CESL layer 580 can extend completely to the edge of Poly-1 530′.

This resulting buried CESL layer 580 can later act as an etch stop, during bitline contact etch, so that bitline contacts, even if misaligned, will stop on the buried CESL layer 580 and not proceed further and go into the silicon 512.

FIG. 19B is a cross-sectional view on a line Y-Y through the view of FIG. 16, and illustrates the same step as FIG. 19A (Buried CESL Fill) in the overall process of forming a self-aligned buried contact etch stop layer (CESL).

FIG. 19C is a cross-sectional view on a line Z-Z through the view of FIG. 16, and illustrates the same step as FIG. 19A (Buried CESL Fill) in the overall process of forming a self-aligned buried contact etch stop layer (CESL).

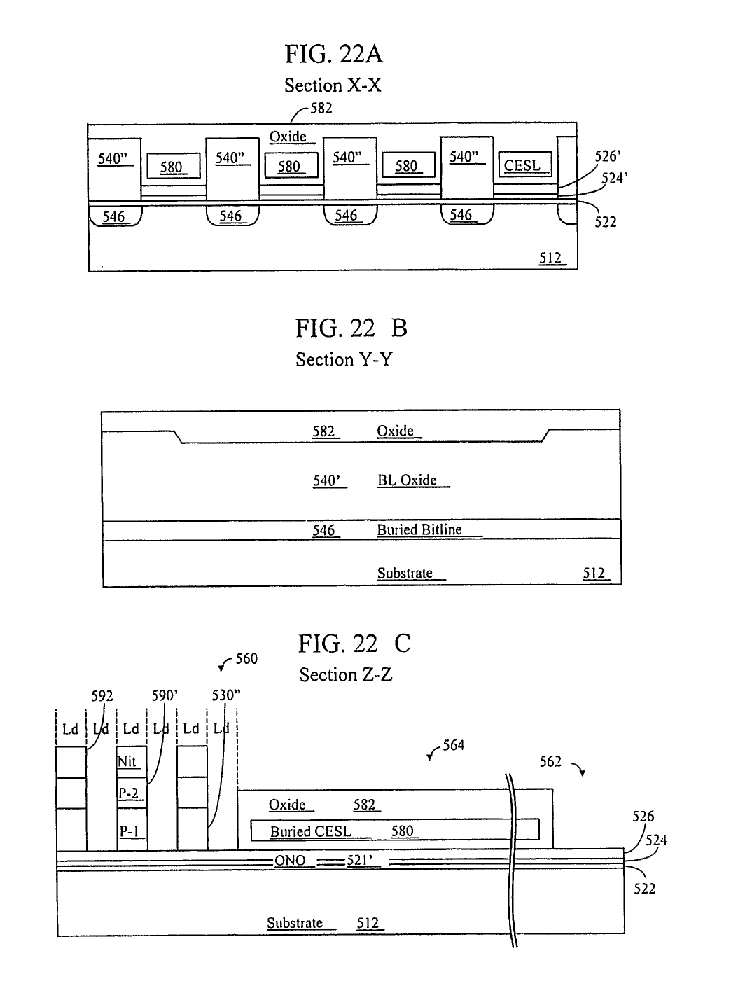

Note that the nitride 532′ is still in place for planarizing (CMP) the oxide fill 582. Here, a purpose of completely surrounding the CESL layer 580 with oxide 582 is apparent. Else, the CESL layer 580 would extend all the way to Poly-1, which is subsequently removed (see FIG. 22C) thereby exposing the CESL layer 580 to the subsequent wet nitride strip.

Alternatively, the CESL layer 580 can extend completely to the edge of Poly-1 530′ and during the subsequent wordline formation additional wordlines on either side of the contact region would need to be formed to protect the Poly-1 edge encapsulating the CESL layer 580

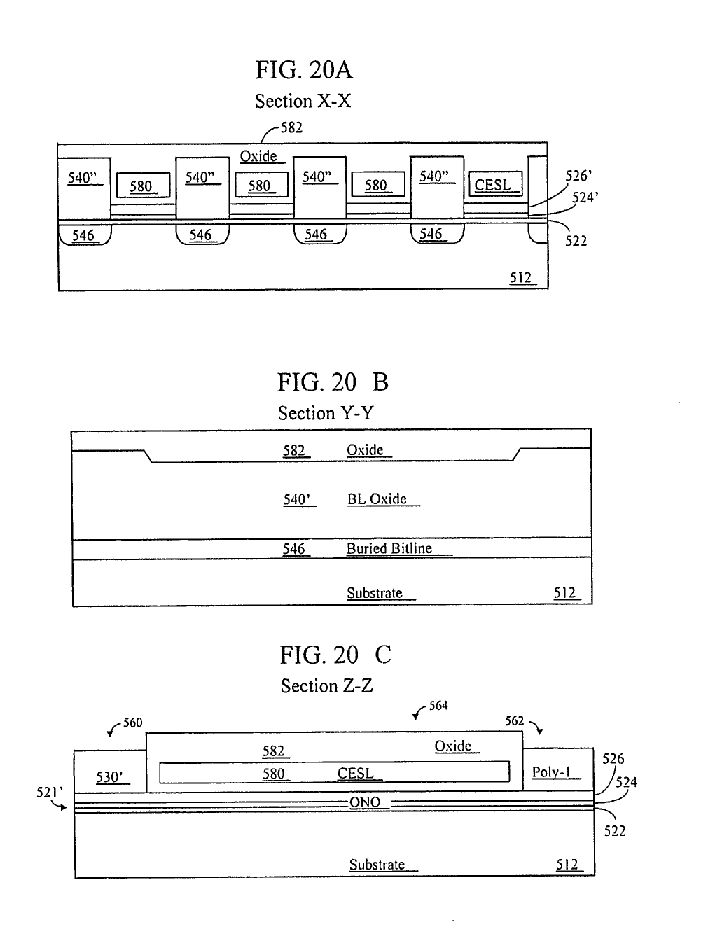

FIG. 20A is a cross-sectional view on a line X-X through the view of FIG. 16, and illustrates a next step (Nitride Strip/Hard Mask Removal) in the overall process of forming a self-aligned buried contact etch stop layer (CESL).

FIG. 20A is generally the same as the previous FIG. 19A, since there is no nitride layer along the section X-X.

FIG. 20B is a cross-sectional view on a line Y-Y through the view of FIG. 16, and illustrates the same step as FIG. 20A (Nitride Strip/Hard Mask Removal) in the overall process of forming a self-aligned buried contact etch stop layer (CESL).

FIG. 20B is generally the same as the previous FIG. 19B, since there is no nitride layer along the section Y-Y.

FIG. 20C is a cross-sectional view on a line Z-Z through the view of FIG. 16, and illustrates the same step as FIG. 20A (Nitride Strip/Hard Mask Removal) in the overall process of forming a self-aligned buried contact etch stop layer (CESL).

A wet etch is performed, and the nitride hard mask 532′ (compare FIG. 19C) is removed. Note that the CESL layer 580 is completely surrounded by oxide 582.

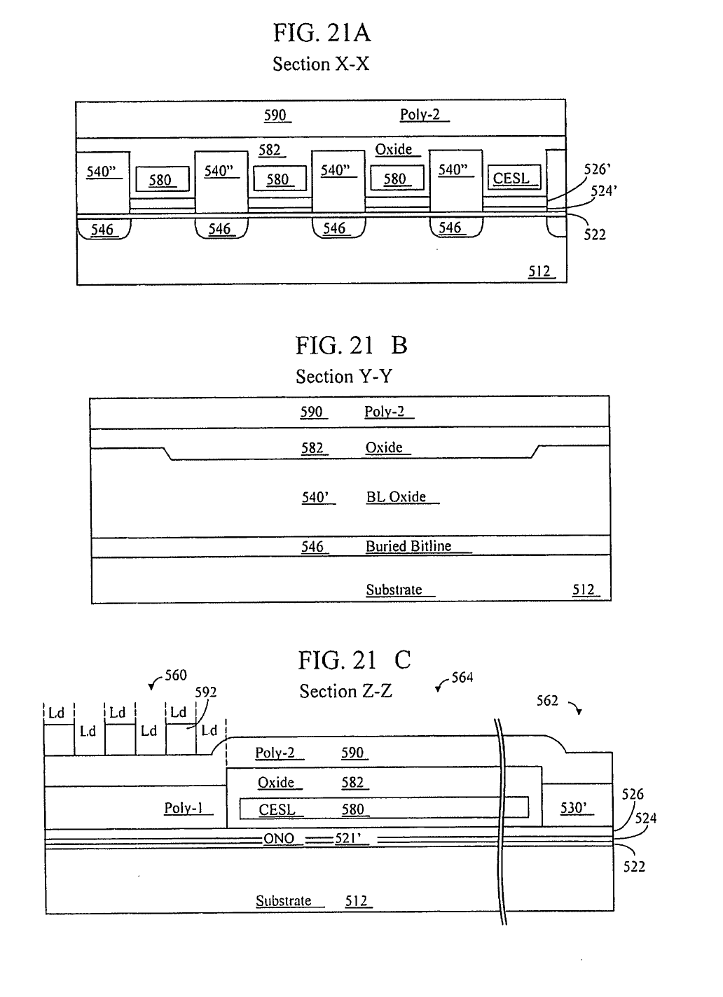

FIG. 21A is a cross-sectional view on a line X-X through the view of FIG. 16, and illustrates a next step (Poly-2 Dep and WL HM) in the overall process of forming a self-aligned buried contact etch stop layer (CESL).

In this step, polysilicon (poly, Poly-2) 590 is deposited. In FIGS. 21A and 21B, Poly-2 590 is atop oxide 582. In FIG. 21C, it can be seen that Poly-2 590 is atop Poly-1530′ (prime, has previously been patterned) and atop the oxide 582 in the contact area 564.

FIG. 21B is a cross-sectional view on a line Y-Y through the view of FIG. 16, and illustrates the same step as FIG. 21A (Poly-2 Dep and WL HM) in the overall process of forming a self-aligned buried contact etch stop layer (CESL).

FIG. 21C is a cross-sectional view on a line Z-Z through the view of FIG. 16, and illustrates the same step as FIG. 21A (Poly-2 Dep and WL HM) in the overall process of forming a self-aligned buried contact etch stop layer (CESL).

A hard mask (HM) 592 is formed atop the Poly-2 590, in the wordline area 560. The hard mask 592 would also be atop the Poly-2 590, in the wordline area 562, but is omitted for illustrative clarity.

In a subsequent step, the wordlines will be etched, through Poly-2 590 and through Poly-1 530′.

Note that the CESL 580 is spaced at least a distance “Ld” (Ld represents a minimum feature dimension) from the wordlines (which will be formed directly under the HM 592).

Alternatively, if the CESL layer 580 extends completely to the edge of Poly-1 530′, an additional wordline may be formed on either side of the contact region and spaced at least a distance Ld from the wordline regions 560 and 562 to protect the Poly-1 edge encapsulating the CESL layer 580. This additional wordline (not shown) may, optionally, be a “dummy” wordline.

In the next step, poly etch is perforned.

FIG. 22A is a cross-sectional view on a line X-X through the view of FIG. 16, and illustrates a next step (WL etch (Poly-2/Poly-1 etch)) in the overall process of forming a self-aligned buried contact etch stop layer (CESL).

Here it can be seen that Poly-2 (590) is etched (removed) from atop the oxide 582.

FIG. 22B is a cross-sectional view on a line Y-Y through the view of FIG. 16, and illustrates the same step as FIG. 22A (WL etch (Poly-2/Poly-1 etch)) in the overall process of forming a self-aligned buried contact etch stop layer (CESL).

Here it can be seen that Poly-2 (590) is etched (removed) from atop the oxide 582.

FIG. 22C is a cross-sectional view on a line Z-Z through the view of FIG. 16, and illustrates the same step as FIG. 22A (WL etch (Poly-2/Poly-1 etch)) in the overall process of forming a self-aligned buried contact etch stop layer (CESL).

In FIG. 22C, it can be seen that Poly-2 590′ (prime) is etched, as well as Poly-1 530″ (double prime), under the hard mask 592, resulting in a plurality of wordlines in the wordline region 560. Wordlines are similarly formed in the wordline region 562.

In FIG. 22C, it can be seen that Poly-2 (590) is etched (removed) from atop the oxide 582, and that there is no poly left in the contact area 560. It is important that the contact region 560 be free of any poly residues.

In FIG. 22C, it can be seen that the CESL layer 580 is completely surrounded by oxide 582. This protects the CESL layer 580 from all further processing (such as nitride etches and spacer formation).

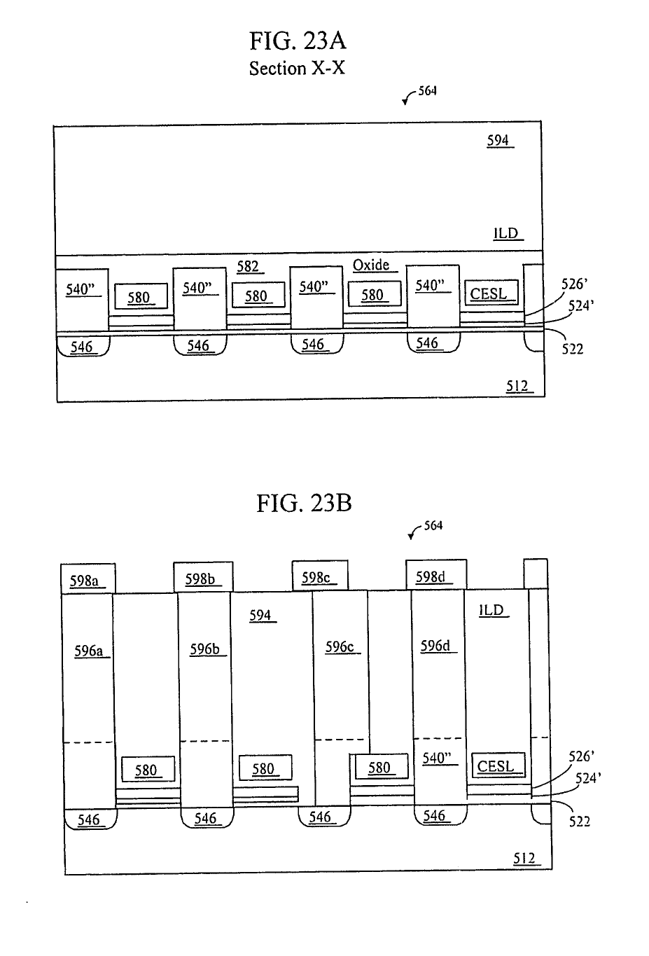

FIG. 23A illustrates a next step in the overall process of forming a self-aligned buried contact etch stop layer (CESL).

Inter-Level Dielectric (ILD) 594, such as oxide, is deposited.

FIG. 23B illustrates a next step (Metal-1 Mask and Etch) in the overall process of forming a self-aligned buried contact etch stop layer (CESL).

Contact holes 596a . . . 596d are formed through the ILD 594. This is done with a mask, and here is where misalignments may occur.

Next the contact holes are filled (with a conductive material, such as metal). And, a pattern of interconnects 598a . . . 598d (Metal-1, M1) may be provided.

The contact hole 596c is shown as being misaligned, stopping on the CESL 580. Since the contact (596c) cannot reach the silicon 512, and as long as it does substantially land on the bitline (546), the misalignment is not a concern. Optionally, the width of the contact holes 596c is such that even in the misaligned case, a full overlap with the bitline (546) is achieved. The portion that land on CESL (580) is not a concern since the CESL is self aligned to the bitline. The full coverage of the contacts by the bitlines may, if necessary, eliminate the use of an additional mask to implant into the contacts.

### ANOTHER EMBODIMENT OF BURIED CESL

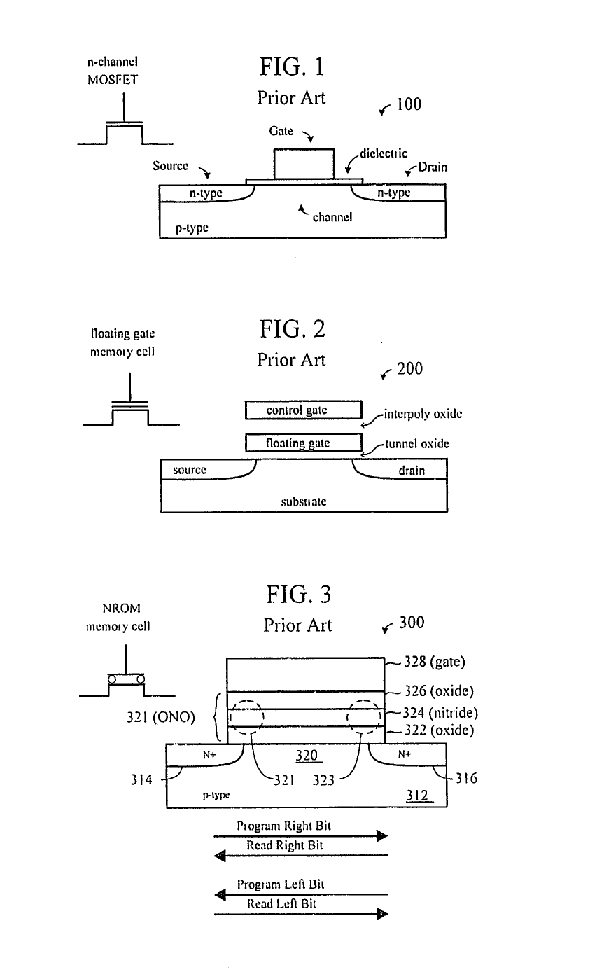

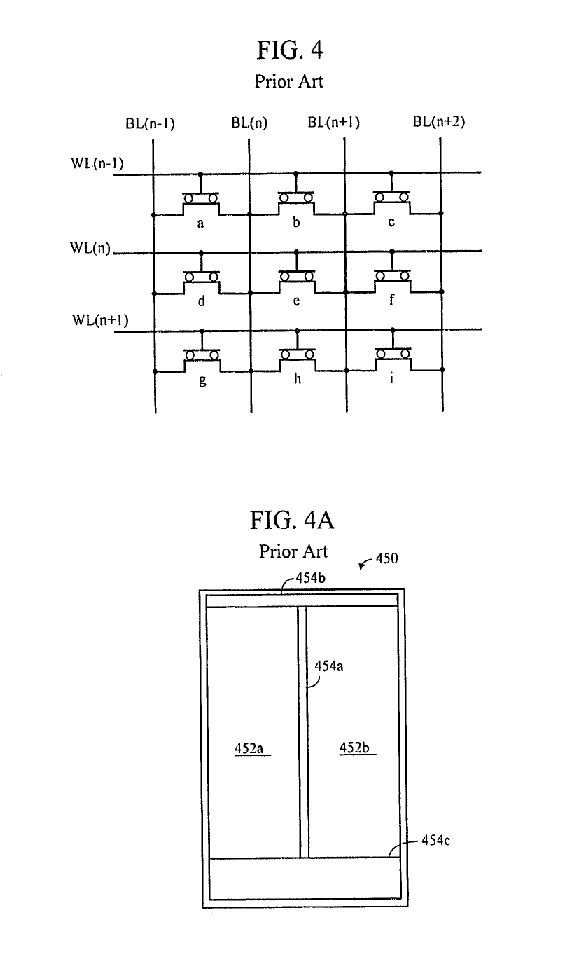

Reference is made to FIGS. 1, 2, 3, 4, 4A and 5 described hereinabove, as though set forth in their entirety herein.

This embodiment provides an alternative technique for forming a buried CESL layer without performing the “dep-etch-dep” steps described with respect to FIGS. 19A-19C.

As discussed hereinabove, with respect to FIG. 5, a contact etch stop layer (CESL) may be formed between each of the adjacent bitlines, such as between BL1 and BL2, between BL2 and BL3, and between BL3 and BL4 and that is self-aligned to these adjacent bitlines or diffusions. The CESL is a layer which is more difficult (resistant) to etch than the layers on top of it and is disposed between the adjacent bitlines. The CESL, may have nearly the same width (horizontal dimension) as the spacing between the bitlines, and is at substantially the same vertical position as the bitline contacts, and should extend vertically beyond the bitline contacts to ensure that any misaligned portion of a bitline contact will “land” on CESL, rather than on silicon, thereby maintaining isolation of adjacent bitlines. The CESL may extend to nearly the full width of the contact region.

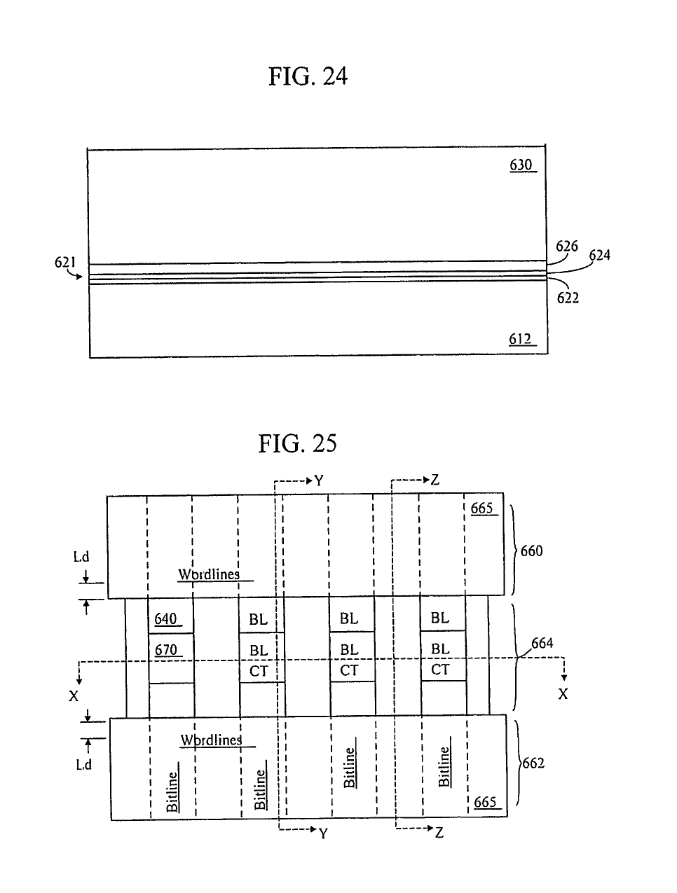

Generally, in the following figures, the reference numerals are incremented by 100 (from the 500-series to the 600-series) for elements that are similar to those described with respect to the previous embodiment. For example, substrate 512 (FIG. 6) is comparable to substrate 612 (FIG. 24).

FIG. 24 (compare FIG. 6) illustrates a first step (Deposit ONO and Poly-1) in an overall process of forming a buried contact etch stop layer (CESL).

An ONO stack 621 (compare 321) comprising a bottom (lower) oxide layer 622 (compare 322), a layer 624 (compare 324) of charge-trapping material such as nitride, and a top (upper) oxide layer 626 (compare 326) is deposited on a substrate 612 (compare 312). The ONO stack 621 may have an overall thickness of approximately 10-50 nm, such as 18 nm, as follows:
the bottom oxide layer 622 may be from 3 to 10 nm, for example 4 nm thick;
the middle nitride layer 624 may be from 3 to 12 nm, for example 4 nm thick; and
the top oxide layer 626 may be from 5 to 25 nm, for example 10 nm thick.

The ONO 612 may be etched (removed) from the periphery (CMOS) area (not shown, compare 454). Generally, ONO 621 will remain over cell wells in the substrate. (The cell well is an area in the silicon substrate that is prepared for functioning as a transistor or memory cell device by doping with an electron acceptor material or with an electron donor material.)

A first layer 630 of polysilicon (“poly”; “Poly-1”) is deposited, to a thickness of approximately 10-250 nm, such as to a thickness of 70 nm, over the ONO 621.

FIG. 25 (compare FIG. 14) illustrates a next step (BL contacts area mask) in the overall process of forming a self-aligned buried contact etch stop layer (CESL).

Note the section lines X-X, Y-Y and Z-Z. In this, and in some subsequent figures:
X-X cross-sections are taken through the contact area 664, at a position where the bitline contacts BLCT 670, described hereinbelow, will be formed.
Y-Y cross-sections are taken through the array, along a bitline (BL) 646, and traverse the contact area 664 into the wordline areas 660 and 662.
Z-Z cross-sections are taken through the array, between bitlines (BL) 646, and traverse the contact area 664 into the wordline areas 660 and 662.

In FIG. 25, and subsequent figures, the reference numeral 640 is used to indicate the bitline oxide, not yet formed. In some figures, the reference numeral 640 may be used to indicate oxide which has been planarized (CMP), rather than using the prime version (640′), for illustrative clarity. The same (reverting to non-prime nomenclature) may be true for other elements, such as ONO 621, for illustrative clarity.

Photoresist (“Resist”) 665 is shown covering (masking) the wordline areas 660 and 662, leaving the contact area 664 exposed, for further processing.

A dimension “Ld” is shown, which indicates a minimum feature size, and the spacing of the first word line in a word line area 660 or 662 from the contact area 664.

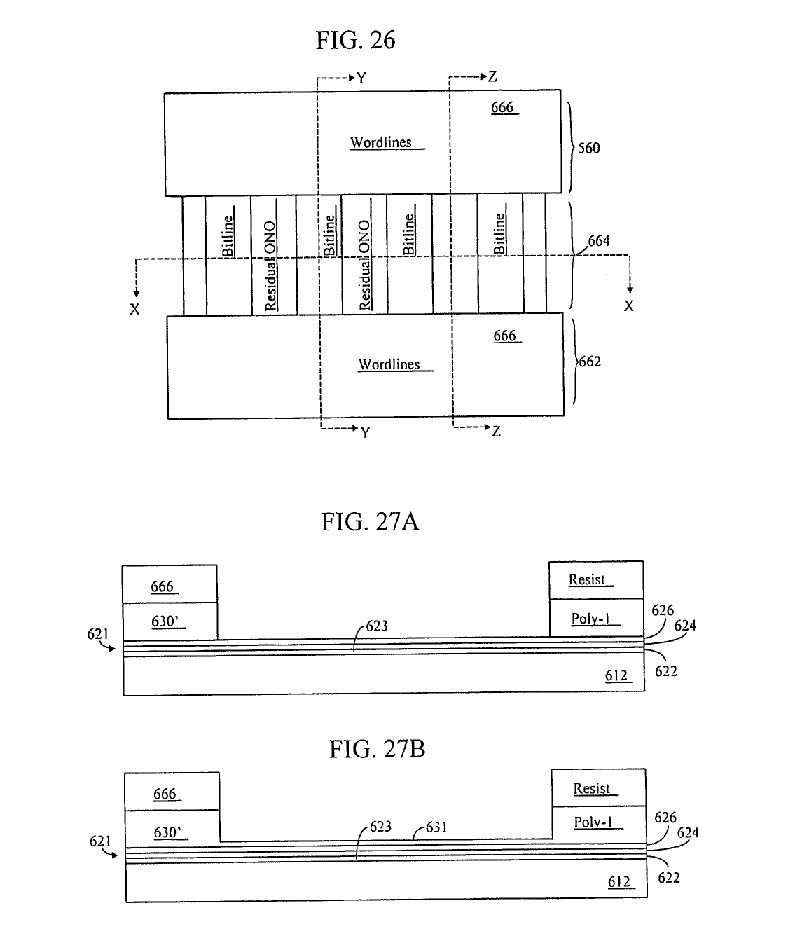

FIG. 26 illustrates a next step (Etch Poly-1) in the overall process of forming a self-aligned buried contact etch stop layer (CESL).

After the Poly-1 etch which is selective to oxide, residual ONO is shown between the bitlines. The wordline areas 660 and 662 are masked, such as with photoresist (resist) 666. In FIG. 26, the Poly-1 in the contact area 664 has been etched.

FIG. 27A illustrates a next step (Contact Area Poly-1 etch) in the overall process of forming a self-aligned buried contact etch stop layer (CESL).

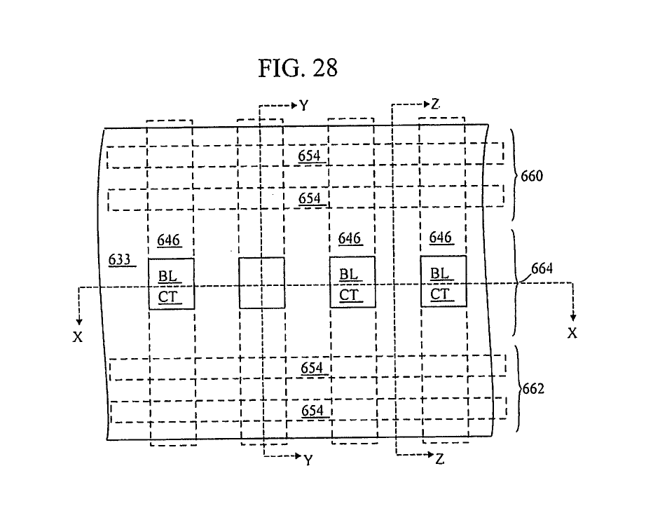

In FIG. 27A, the Poly-1 630 is etched in the contact area 664, and is indicated as 630′ (prime). The etch stops on the top oxide 626 of the ONO 621. A layer of thin polysilicon (poly) will be deposited in the next step (FIG. 28).

Alternatively, FIG. 27D illustrates an alternative next step (Contact Area Poly-1 etch) in the overall process of forming a self-aligned buried contact etch stop layer (CESL).

In FIG. 27B, the Poly-1 630 is etched (and indicated as 630′, prime) in the contact area 664, leaving about 10 nm of Poly-1 to act as a Nitride HM etch stop. The remaining “residual” poly is labeled 631.

For convenience and clarity of presentation the alternative approach outlined in FIG. 27B will not be discussed further and instead the thin poly deposition outlined in FIG. 28 will be covered instead.

If necessary, in either of these alternatives (FIG. 27A, FIG. 27B), an implant 623 can be performed to prevent leakage between the contacts. The leakage prevention implant 623 is omitted from subsequent figures, for illustrative clarity.

FIG. 28 illustrates a next step (Bit Line Formation) in the overall process of forming a self-aligned buried contact etch stop layer (CESL). Note the section lines X-X, Y-Y and Z-Z.

In this step, the resist 666 is stripped, and a layer of thin poly 633 is deposited over the entire array.

The layer 633 may be deposited to a thickness of approximately 5-50 nm, such as to a thickness of approximately 10 nm. The thickness of layer 633 depends on the etch selectivity between nitride and poly and on the amount of overetch needed. The thin poly layer 633 may be deposited over the entire array.

Wordlines 654 are illustrated, but are not yet formed. Bitlines 646 are illustrated, but are not yet formed. Bitline contacts BLCT are illustrated, but are not yet formed.

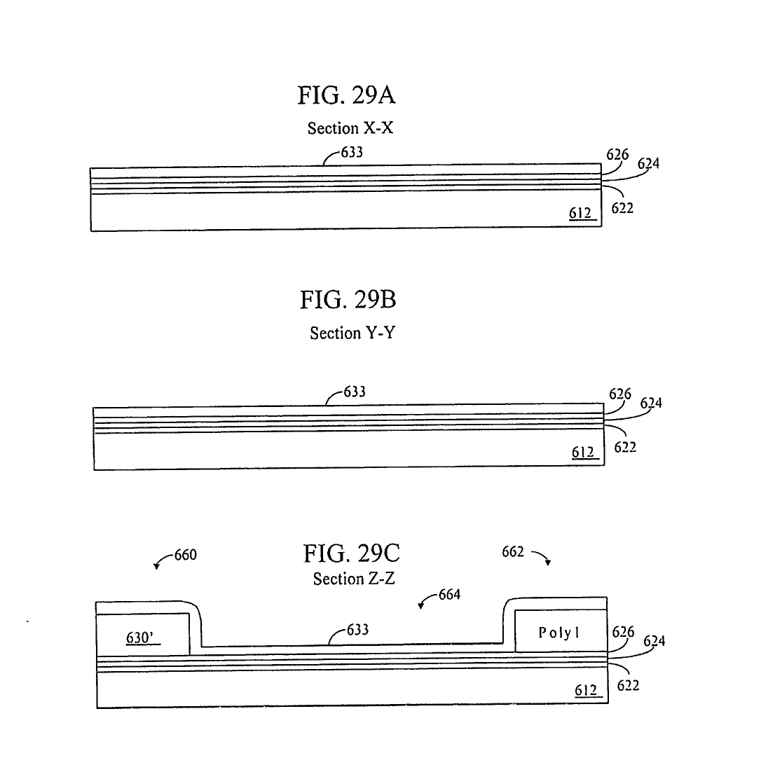

FIG. 29A is a cross-sectional view on a line X-X through the view of FIG. 28, and illustrates a next step (Thin Poly Deposition) in the overall process of forming a self-aligned buried contact etch stop layer (CESL).

This step (thin poly deposition) is based on the step described in FIG. 27A (etch poly, stopping on top ONO oxide).

A layer 633 of polysilicon (poly) is deposited to a thickness of approximately 5-50 nm, such as to a thickness of approximately 10 nm. The thin poly layer 633 is over the ONO 621 in this section.

FIG. 29B is a cross-sectional view on a line Y-Y through the view of FIG. 28, and illustrates the same step as FIG. 29A (Thin Poly Deposition) in the overall process of forming a self-aligned buried contact etch stop layer (CESL).

A layer 633 of polysilicon (poly) is deposited to a thickness of approximately 5-50 nm, such as to a thickness of approximately 10 nm. The thin poly layer 633 is over the ONO 621 in this section.

FIG. 29C is a cross-sectional view on a line Z-Z through the view of FIG. 28, and illustrates the same step as FIG. 29A (Thin Poly Deposition) in the overall process of forming a self-aligned buried contact etch stop layer (CESL).

A layer 633 of polysilicon (poly) is deposited to a thickness of approximately 5-50 nm, such as to a thickness of approximately 10 nm. In this section, the thin poly layer 633 is over the ONO 621 in the contact region 664, and is over Poly-1 630′ in the word line regions 660 and 662.

The thickness (greater or less than 10 nm) of the layer 633 should be based on the nitride hard mask over etch (described below), which should terminate on the thin poly 633 in the contact area 664.

The thin poly 633 will remain as part of the buried nitride (CESL) structure, described hereinbelow, and should not be detrimental to device performance.

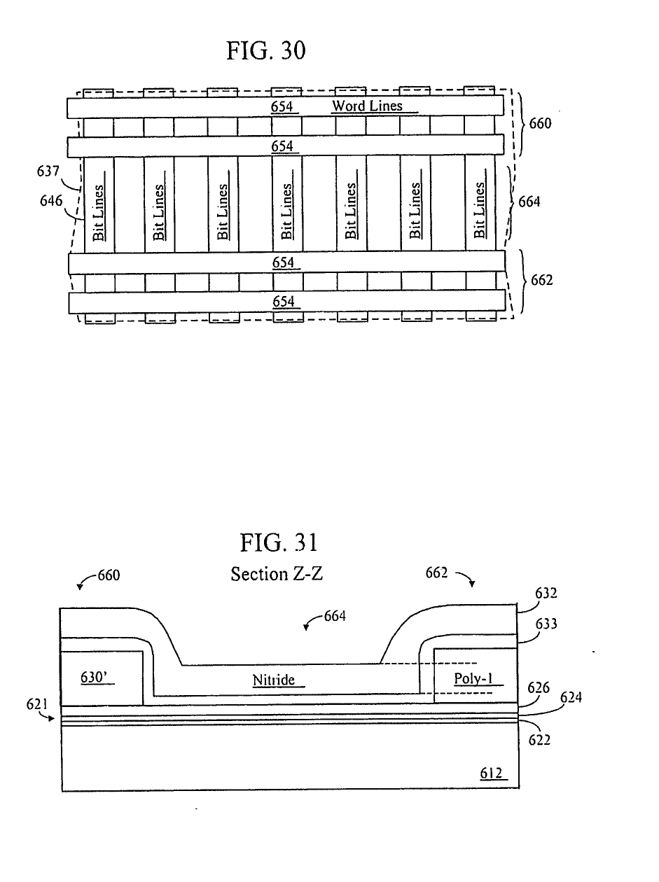

FIG. 30 illustrates a next step (Nitride hard Mask deposition and Bitline Mask & Etch) in the overall process of forming a self-aligned buried contact etch stop layer (CESL).

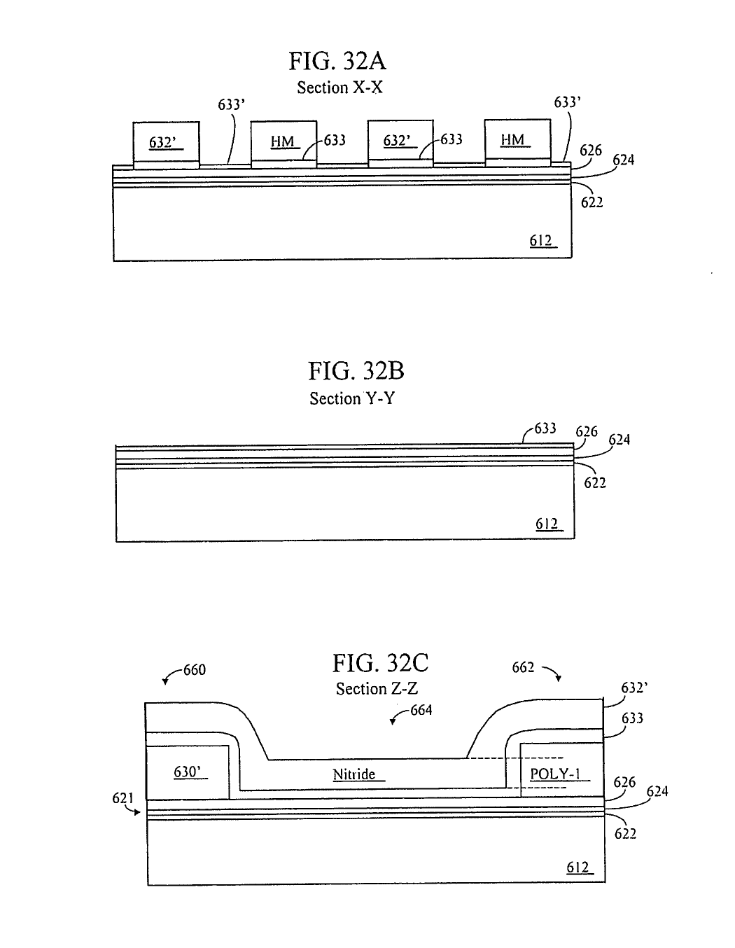

As described with respect the FIG. 31 and FIGS. 32A-32C, a layer 637 of nitride (dashed lines) is deposited over the entire array, and patterned to be a hard mask 632. Portions of the hard mask will become the buried CESL layer 680, as described in greater detail hereinbelow.

FIG. 31 illustrates the same step as FIG. 30 (Nitride Hard Mask Deposition & Etch) in the overall process of forming a self-aligned buried contact etch stop layer (CESL). This figure is a “Z-Z” section.

In this step, nitride hard mask (HM) material 632 is deposited, over the thin poly 633, and may have a thickness of approximately 30 nm-100 nm.

Note in this drawing that the nitride 632 is on the thin poly 633 in the contact area, which has an exemplary thickness of 10 nm.

Therefore, since the Poly-1 630′ has an exemplary thickness of 70 nm, the top surface of the nitride 632 is slightly below the top surface of the Poly-1 630 or below the thin poly 633 atop Poly-1 630.

A bitline (BL mask) 637 is shown in FIG. 30, and a Nitride HM etch is described in the next step (with respect to the following figures).

Next, the nitride hard mask 632 will be etched, stopping on the thin poly 633 in the contact area.

FIG. 32A is a cross-sectional view on a line X-X through the view of FIG. 28, and illustrates a next step (Nitride Hard Mask etch) in the overall process of forming a self-aligned buried contact etch stop layer (CESL).

The nitride hard mask 632 is etched, resulting in a pattern of nitride structures 632′. As can be seen, the thin poly layer 633 is slightly etched where it is not under the nitride hard mask (HM) 632′. It retains its original thickness of 10 nm under the nitride hard mask. Outside of the Nitride Hard Mask, the thin poly layer 633 has its thickness reduced by the nitride hard mask overetch portion, and is referenced as 633′ (prime).

FIG. 32B is a cross-sectional view on a line Y-Y through the view of FIG. 28, and illustrates the same step as FIG. 32A (Nitride Hard Mask etch) in the overall process of forming a self-aligned buried contact etch stop layer (CESL).

FIG. 32B shows a thinned down layer 633′ of the thin poly (to approximately 5 nm) resulting from the nitride hard mask overetch.

FIG. 32C is a cross-sectional view on a line Z-Z through the view of FIG. 28, and illustrates the same step as FIG. 32A (Nitride Hard Mask etch) in the overall process of forming a self-aligned buried contact etch stop layer (CESL).

This is the same as FIG. 31, because the contact area is masked (see 637, FIG. 30).

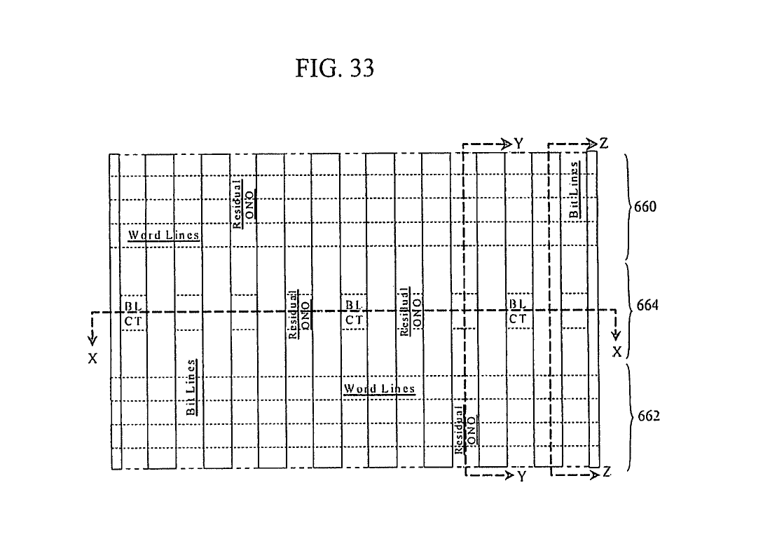

FIG. 33 provides an overview of a next step (Poly-1 etch) in the overall process of forming a self-aligned buried contact etch stop layer (CESL). Note the section lines X-X, Y-Y and Z-Z.

In this step, Poly-1 is etched, stopping on ONO. In the contact area 634 this step will only etch the thinned down thin poly over the bitline areas. This accounts for the appearance of just the residual ONO in between the Nitride Hard mask.

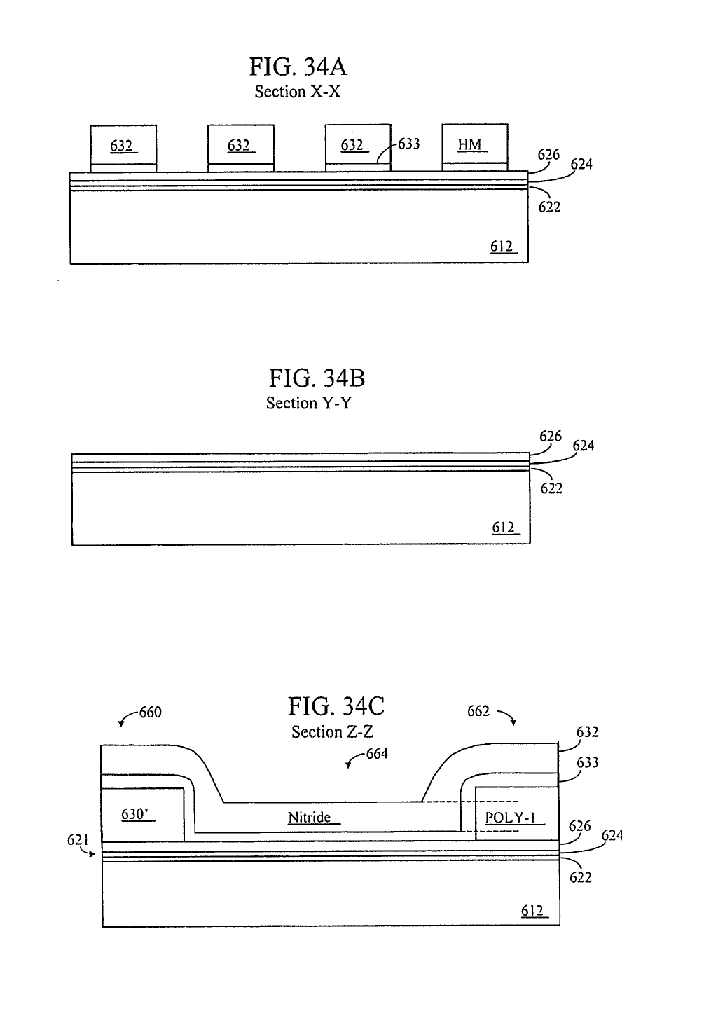

FIG. 34A is a cross-sectional view on a line X-X through the view of FIG. 33, and illustrates a next step (Poly-1 etch) in the overall process of forming a self-aligned buried contact etch stop layer (CESL).

There is no Poly-1 630 in the contact area. It was etched in FIG. 26. This Poly-1 etch will therefore only etch the thin poly 633 between the hard mask 632 and then stop on the top oxide layer 626 of the ONO. FIG. 34A is similar to FIG. 32A, but without the thin poly 633 outside of the HM 632.

In this, and subsequent figures, the nitride 632′ may be referred to simply by the reference numeral 632 (no prime), for illustrative clarity.

FIG. 34B is a cross-sectional view on a line Y-Y through the view of FIG. 33, and illustrates the same step (Poly-1 etch) as FIG. 34A in the overall process of forming a self-aligned buried contact etch stop layer (CESL).

FIG. 34B is similar to FIG. 32B, but without the thin poly 633 outside of the HM 632.

FIG. 34C is a cross-sectional view on a line Z-Z through the view of FIG. 33, and illustrates the same step (Poly-1 etch) as FIG. 34A in the overall process of forming a self-aligned buried contact etch stop layer (CESL).

FIG. 34C is identical to FIG. 32C.

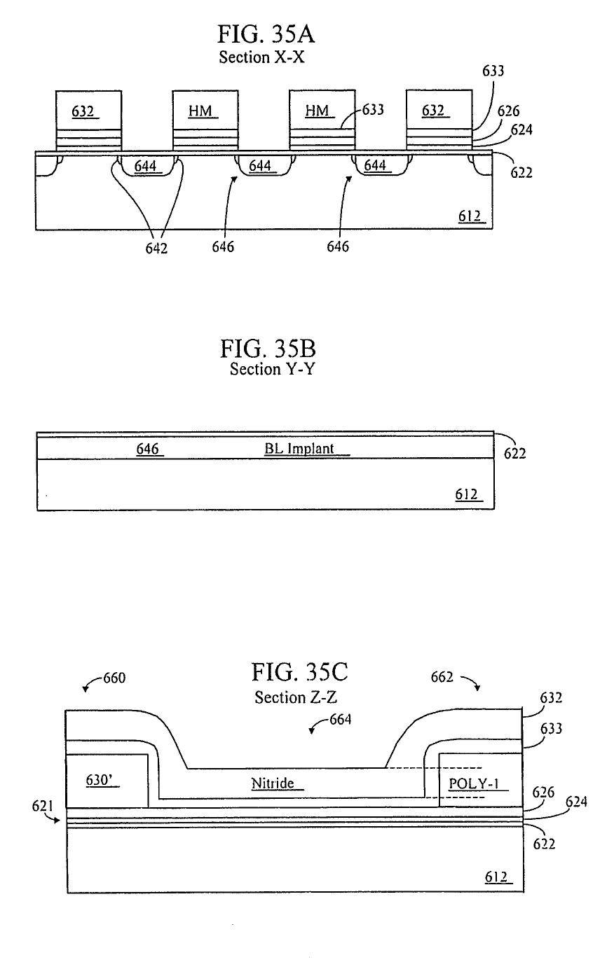

FIG. 35A is a cross-sectional view on a line X-X through the view of FIG. 33, and illustrates a next step (BL Implant) in the overall process of forming a self-aligned buried contact etch stop layer (CESL).

First, the ONO 621 is etched, stopping on the bottom oxide 622.

Then, a bitline (BL) implant is performed. A pocket implant 642 may optionally be formed, followed by a bit line implant 644. Some exemplary process parameters are:
for the pocket implant 642, 0.5−6×10¹³/cm2 (dose of the dopant per unit area) and energy of 10-20 Kev, no tilt, boron (B), although the scope of the disclosure is not limited in this respect.
for the bitline implant 644, 1.0-1.5E′⁵ cm2, 10-20 Kev, Arsenic (As), through the ONO Bottom Oxide, although the scope of the disclosure is not limited in this respect.

The resulting “buried bitline” 646, comprising pocket implant 642 and 644 is situated substantially in the space between adjacent poly structures 630, and extends into the surface of the silicon 612, such as to an exemplary depth of 200 nm. These buried bitlines 646 will act as source and drain diffusions (compare 314 and 316) of memory cells, and the poly lines 630 will function as the gate (compare 328) of the memory cells.

The bitlines 646 (also 546) constitute diffusions, between which a self-aligned contact etch stop layer (680, 580) will be formed. In subsequent figures, the overall buried bitline (BB) may simply be labeled “646”.

During bitline implant, the thickness of the nitride HM 632 should block the BL implant from penetrating the channel region in the contact area, and elsewhere. The channel region (compare 320) is a portion of the silicon 612 which is between the bitlines 646.

FIG. 35B is a cross-sectional view on a line Y-Y through the view of FIG. 33, and illustrates the same step (BL Implant) as FIG. 35A in the overall process of forming a self-aligned buried contact etch stop layer (CESL).

FIG. 35C is a cross-sectional view on a line Z-Z through the view of FIG. 33, and illustrates the same step (BL Implant) as FIG. 35A in the overall process of forming a self-aligned buried contact etch stop layer (CESL).

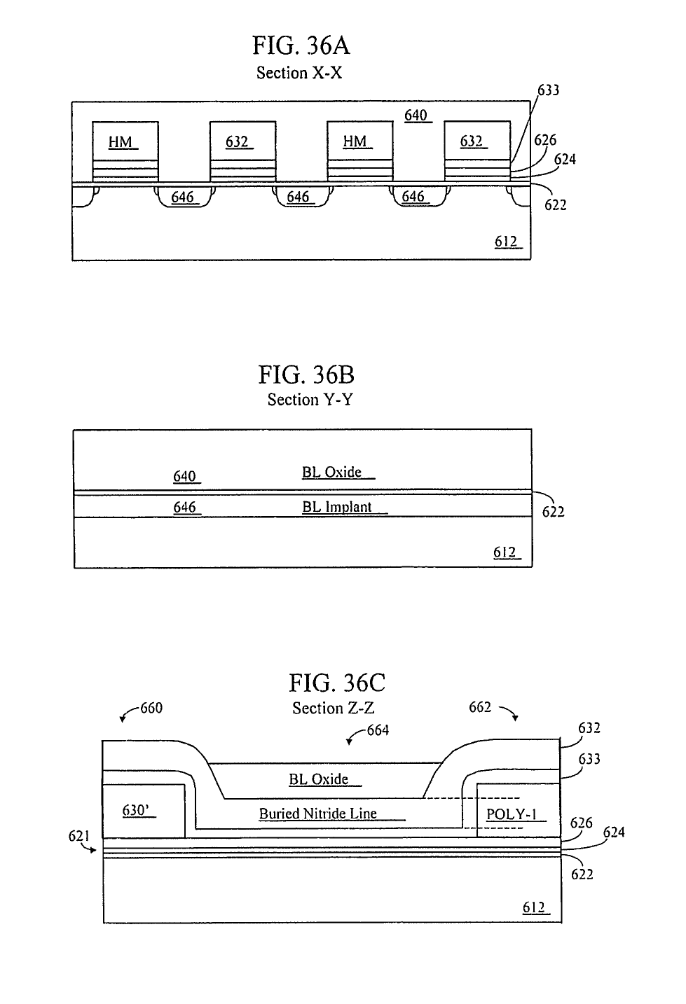

FIG. 36A is a cross-sectional view on a line X-X through the view of FIG. 33, and illustrates a next step (BL Formation, Oxide Fill and CMP) in the overall process of forming a self-aligned buried contact etch stop layer (CESL).

Oxide 640 is deposited, and may be planarized by chemical mechanical polishing (CMP).

FIG. 36B is a cross-sectional view on a line Y-Y through the view of FIG. 33, and illustrates the same step (BL Formation, Oxide Fill and CMP) as FIG. 36A in the overall process of forming a self-aligned buried contact etch stop layer (CESL).

FIG. 36C is a cross-sectional view on a line Z-Z through the view of FIG. 33, and illustrates the same step (BL Formation, Oxide Fill and CMP) as FIG. 36A in the overall process of forming a self-aligned buried contact etch stop layer (CESL).

In this figure, the nitride 632 (which is the exemplary CESL), now buried under oxide 640, is referred to as “Buried Nitride Line”.

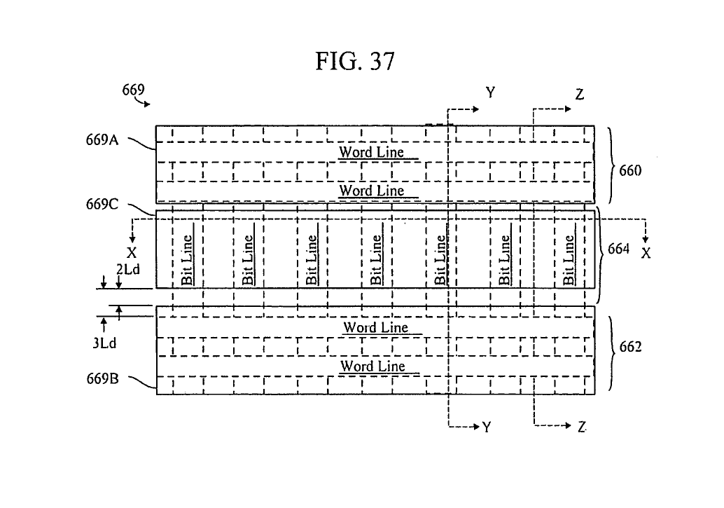

FIG. 37 illustrates a next step (Contact Border Mask) in the overall process of forming a self-aligned buried contact etch stop layer (CESL). Note the section lines X-X, Y-Y and Z-Z.

A mask 669 is formed, having three portions.
A first wordline portion 669A of the mask 669 covers the wordline region 660.
A second wordline portion 669B of the mask 669 covers the wordline region 662.
A third, center portion 669C of the mask 669 covers the central portion of the contact region 664.

The distance “2Ld” represents the separation between a top or bottom edge of the center portion 669C of the mask and the neighboring wordline portions of the mask 669A or 669B, respectively. Thus, on both the top and bottom (as viewed) portions of the contact region 664, adjacent the wordline regions 660 and 662, respectively, a space 2Ld is open (not masked), for further processing.

The distance “3Ld” represents the separation between a top or bottom edge of the center portion 669C of the mask 669 and a first wordline in the neighboring wordline region 660 or 662, respectively.

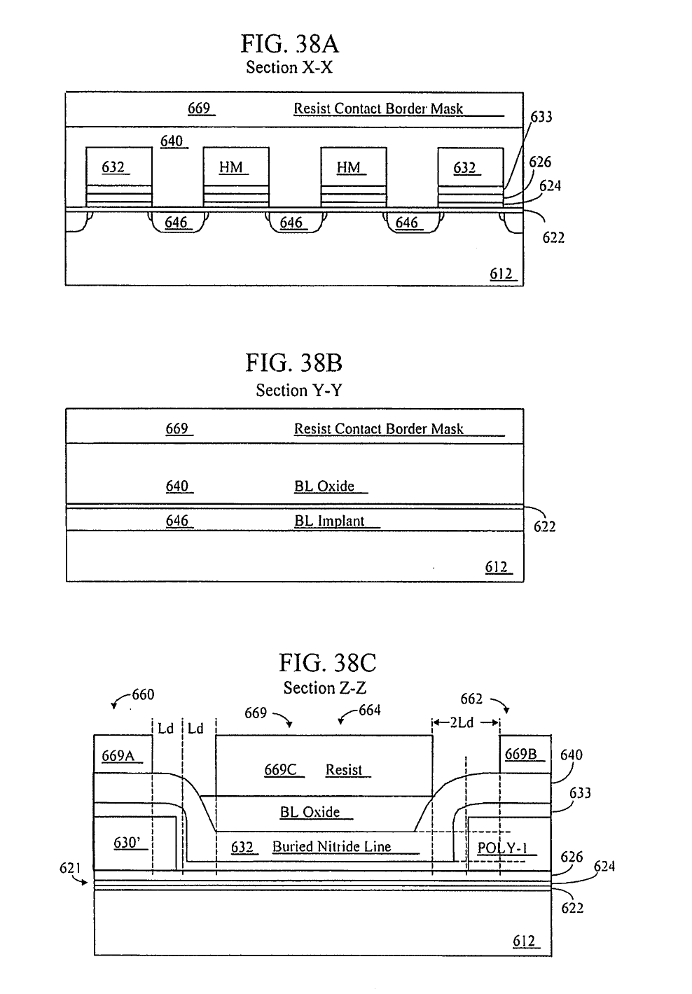

FIG. 38A is a cross-sectional view on a line X-X through the view of FIG. 37, and illustrates the same step (Contact Border Mask) as FIG. 37 in the overall process of forming a self-aligned buried contact etch stop layer (CESL).

FIG. 38B is a cross-sectional view on a line Y-Y through the view of FIG. 37, and illustrates the same step (Contact Border Mask) as FIG. 37 in the overall process of forming a self-aligned buried contact etch stop layer (CESL).

FIG. 38C is a cross-sectional view on a line Z-Z through the view of FIG. 37, and illustrates the same step (Contact Border Mask) as FIG. 37 in the overall process of forming a self-aligned buried contact etch stop layer (CESL).

In FIG. 38C, the distance 2Ld between the central portion 669C of the mask 669 and the two adjacent wordline portions 669A and 669B can be seen.

In the next step, nitride and oxide will be etched. This may, optionally, be a timed etch, stopping on Poly-1.

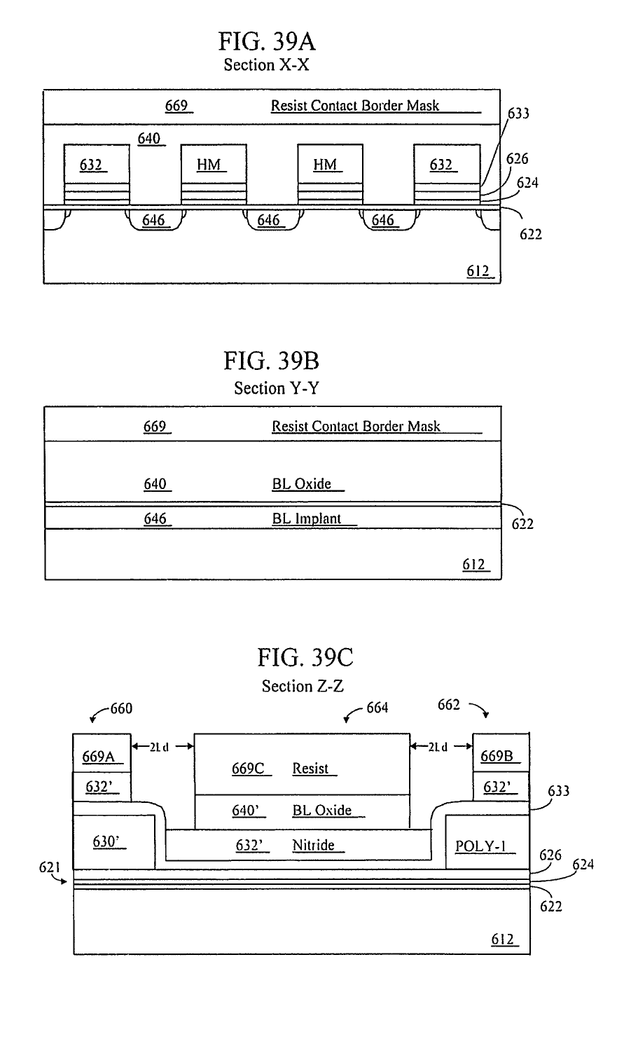

FIG. 39A is a cross-sectional view on a line X-X through the view of FIG. 37, and illustrates a next step (Contact Border Etch) in the overall process of forming a self-aligned buried contact etch stop layer (CESL).

The X-X section shown in FIG. 39A is covered by resist 669 and is not affected by the etch. The X-X section shown in FIG. 39A is substantially the same as the X-X section shown in FIG. 38A.

FIG. 39B is a cross-sectional view on a line Y-Y through the view of FIG. 37, and illustrates the same step (Contact Border Etch) as FIG. 39A in the overall process of forming a self-aligned buried contact etch stop layer (CESL).

The Y-Y section shown in FIG. 39B is covered by resist 669 and is not affected by the etch. The Y-Y section shown in FIG. 39B is substantially the same as the Y-Y section shown in FIG. 38B.

FIG. 39C is a cross-sectional view on a line Z-Z through the view of FIG. 37, and illustrates the same step (Contact Border Etch) as FIG. 39A in the overall process of forming a self-aligned buried contact etch stop layer (CESL).

The nitride and oxide are shown etched in the cross-section of FIG. 39C. This may, optionally, be a timed etch, stopping on Poly-1 630. Depending on the etch selectivities the thin poly 633 and some portion of Poly-1 630 may be etched.

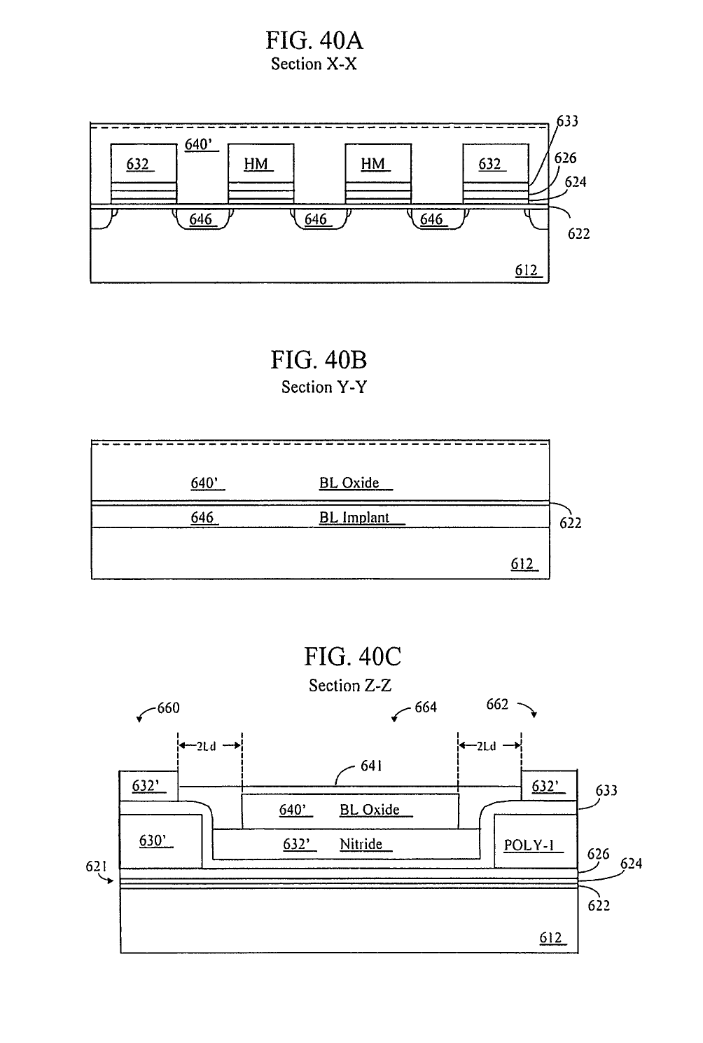

The Nitride on Poly-1 will serve as a CMP etch stop, see FIG. 40

FIG. 39C shows the etched bitline oxide 640′ (prime), and the etched nitride 632′ (prime).

In the next step, the resist 669 is stripped, and additional oxide 641 is deposited in the contact area 664.

FIG. 40A is a cross-sectional view on a line X-X through the view of FIG. 37, and illustrates a next step (Buried Nitride Seal) in the overall process of forming a self-aligned buried contact etch stop layer (CESL).

In this figure, additional oxide 641 over BL oxide 640′ is indicated by a dashed line.

FIG. 40B is a cross-sectional view on a line Y-Y through the view of FIG. 37, and illustrates the same step (Buried Nitride Seal) as FIG. 40A in the overall process of forming a self-aligned buried contact etch stop layer (CESL).

In this figure, additional oxide 641 over BL oxide 640′ is indicated by a dashed line.

FIG. 40C is a cross-sectional view on a line Z-Z through the view of FIG. 37, and illustrates the same step (Buried Nitride Seal) as FIG. 40A in the overall process of forming a self-aligned buried contact etch stop layer (CESL).

Here it can be seen that the nitride 632′ is totally enclosed by poly 633 on its bottom and side surfaces, and by oxide 640′ and 641 on its top and the bitline sides.

In FIG. 40C, the additional oxide fill 641 is shown over the original bitline oxide 640 for illustrative clarity, but in practice, the resulting structure of two oxides may in fact be slightly thinner than the original BL oxide, after CMP. However, the additional oxide fill 641 is not shown, distinctly, over the original BL oxide in FIGS. 40A and 40B.

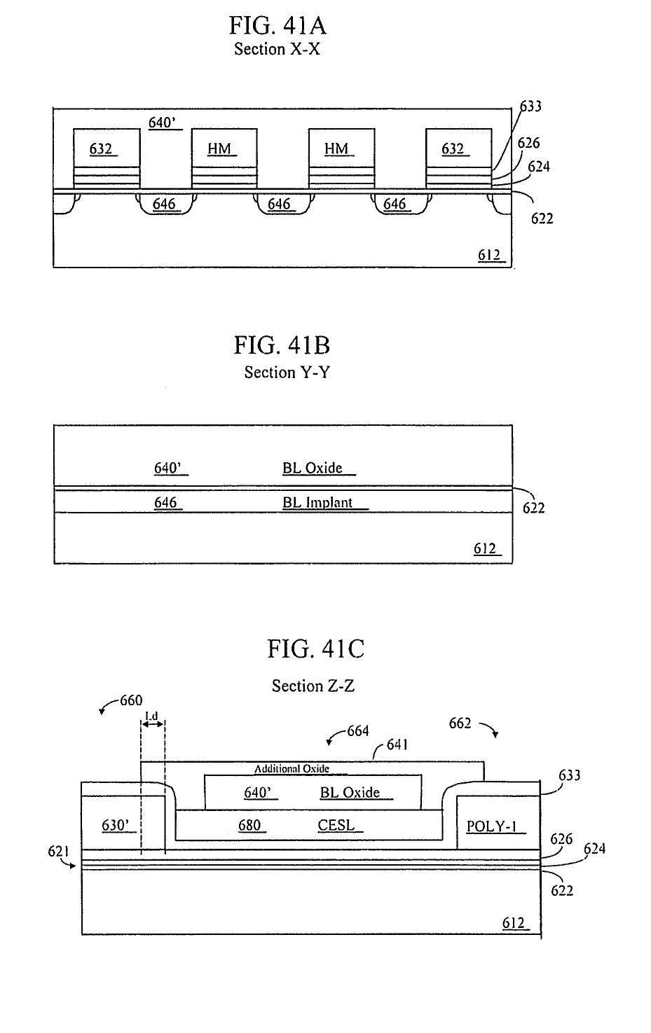

FIG. 41A is a cross-sectional view on a line X-X through the view of FIG. 37, and illustrates a next step (Wet Nitride Strip) in the overall process of forming a self-aligned buried contact etch stop layer (CESL).

The X-X section shown in FIG. 41A is substantially the same as the X-X section shown in FIG. 40A.

FIG. 41B is a cross-sectional view on a line Y-Y through the view of FIG. 37, and illustrates the same step (Wet Nitride Strip) as FIG. 41A in the overall process of forming a self-aligned buried contact etch stop layer (CESL).

The Y-Y section shown in FIG. 41B is substantially the same as the Y-Y section shown in FIG. 39A.

FIG. 41C is a cross-sectional view on a line Z-Z through the view of FIG. 37, and illustrates the same step (Wet Nitride Strip) as FIG. 41A in the overall process of forming a self-aligned buried contact etch stop layer (CESL).

The Z-Z section shown in FIG. 41C is similar to the Z-Z section shown in FIG. 39A, but with the nitride 632 (632′) which is over Poly-1 630′ removed.

The nitride 632′ in the contact area 664 is protected by BL oxide 640′, and is not removed, and remains in place as a contact etch stop layer (CESL) 680 (compare 580).

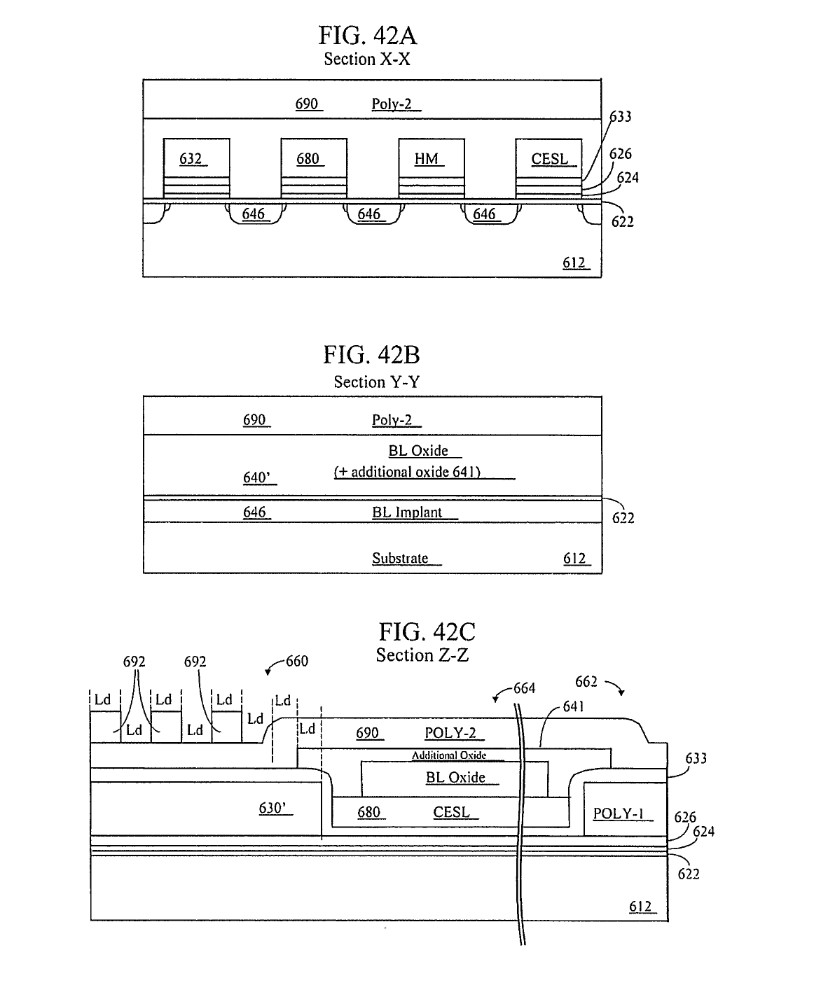

FIG. 42A (compare FIG. 21A) is a cross-sectional view on a line X-X through the view of FIG. 37, and illustrates a next step (Poly-2 Deposition and WL Mask) in the overall process of forming a self-aligned buried contact etch stop layer (CESL).

The nitride hard mask (HM) 632 becomes the buried nitride layer (CESL) 680 in this embodiment. It is evident that the CESL 680 has better coverage in this embodiment than the CESL 580 in the previous embodiment, but the process is somewhat more complicated. Compare FIG. 42A (this embodiment) with FIG. 23A (previous embodiment).

FIG. 42B (compare FIG. 21B) is a cross-sectional view on a line Y-Y through the view of FIG. 37, and illustrates the same step (Poly-2 Deposition and WL Mask) as FIG. 42A in the overall process of forming a self-aligned buried contact etch stop layer (CESL).

FIG. 42C (compare FIG. 21C) is a cross-sectional view on a line Z-Z through the view of FIG. 37, and illustrates the same step (Poly-2 Deposition and WL Mask) as FIG. 42A in the overall process of forming a self-aligned buried contact etch stop layer (CESL).

A hard mask 692 is formed atop the Poly-2 690, in the wordline area 660. The hard mask 692 would also be atop the Poly-2 690, in the wordline area 662, but is omitted for illustrative clarity.

In a subsequent step, the wordlines will be etched, through Poly-2 690 and through Poly-1 630′.

Note that the CESL 680 is spaced at least a distance “2Ld” (Ld represents a minimum feature dimension) from the wordlines (which will be formed directly under the HM 692).

In the next step, poly etch is performed.

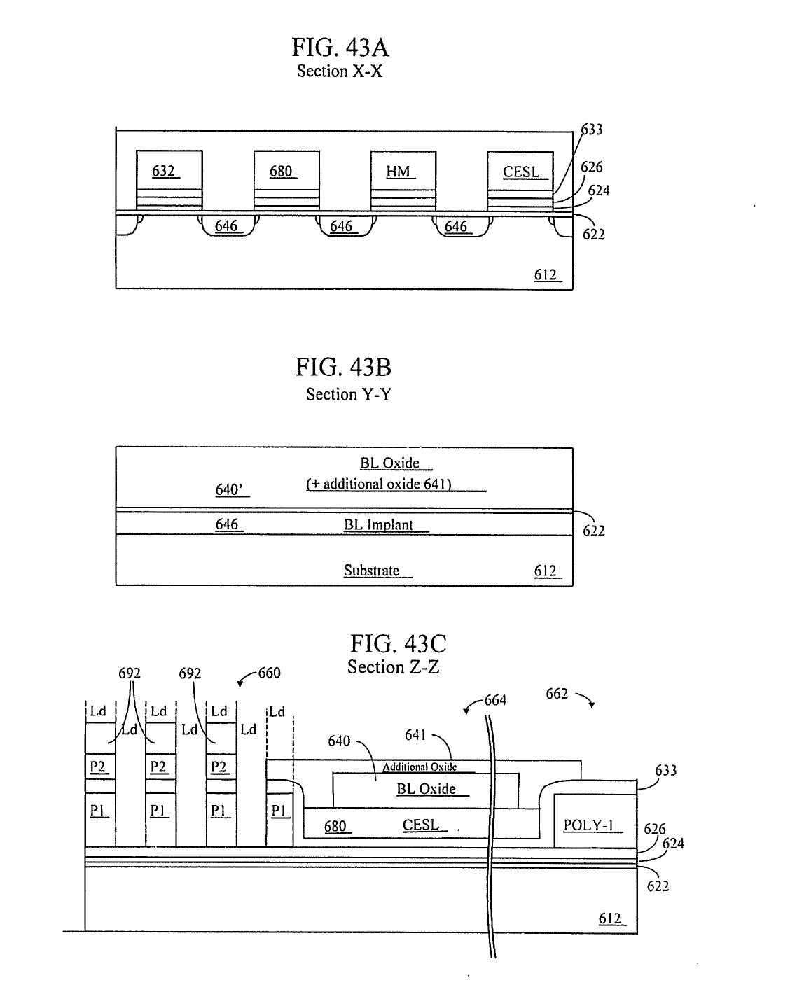

FIG. 43A (compare FIG. 22A) is a cross-sectional view on a line XX-XX through the view of FIG. 37, and illustrates a next step (WL Etch (Poly-2/Poly-1 Etch)) in the overall process of forming a self-aligned buried contact etch stop layer (CESL).

Here it can be seen that Poly-2 (590) is etched (removed) from atop the oxide 640′.

FIG. 43B (compare FIG. 22B) is a cross-sectional view on a line YY-YY through the view of FIG. 37, and illustrates the same step (WL Etch (Poly-2/Poly-1 Etch)) as FIG. 43A in the overall process of forming a self-aligned buried contact etch stop layer (CESL).

Here it can be seen that Poly-2 (590) is etched (removed) from atop the oxide 640′.

FIG. 43C (compare FIG. 22C) is a cross-sectional view on a line ZZ-ZZ through the view of FIG. 37, and illustrates the same step (WL Etch (Poly-2/Poly-1 Etch)) as FIG. 43A in the overall process of forming a self-aligned buried contact etch stop layer (CESL).

In FIG. 43C, it can be seen that Poly-2 690′ (prime) is etched, as well as Poly-1 630″ (double prime), under the hard mask 692, resulting in a plurality of wordlines in the wordline region 660. Wordlines are similarly formed in the wordline region 662.

In FIG. 43C, it can be seen that Poly-2 (690) is etched (removed) from atop the oxide 682, and that there is no poly left in the contact area 660. It is important that the contact region 660 be free of any poly residues.

In FIG. 43C, it can be seen that the CESL layer 680 is completely surrounded by oxide 682. This is important to protect the CESL from all further processing (such as nitride etches and spacer formation).

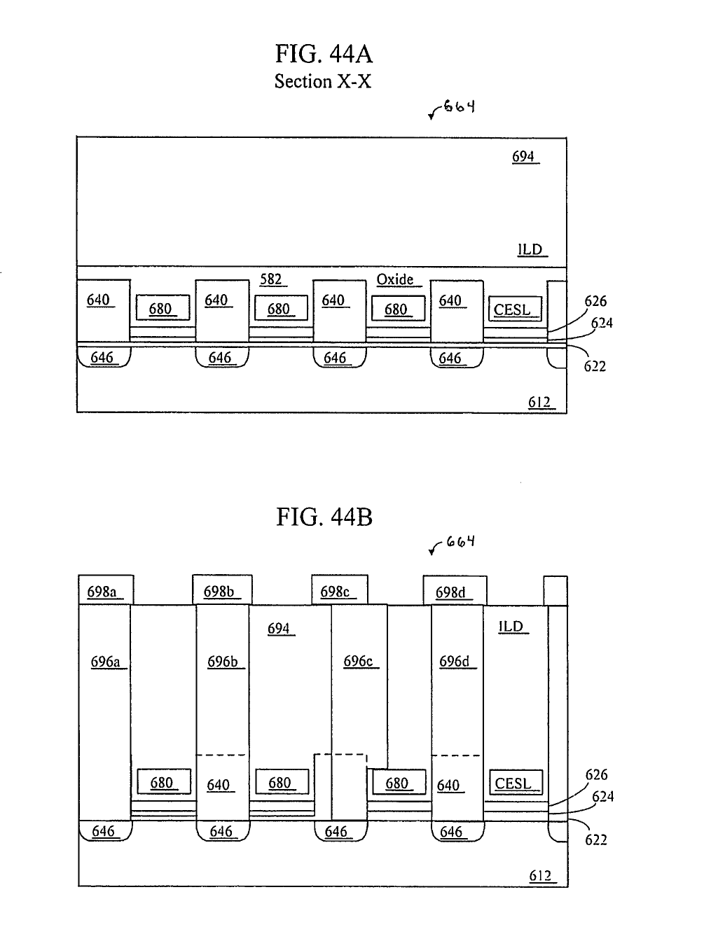

FIG. 44A (compare FIG. 23A) illustrates a next step (Metal-1 Mask and Etch) in the overall process of forming a self-aligned buried contact etch stop layer (CESL).

Inter-Level Dielectric 694, such as oxide, is deposited.

FIG. 44B (compare FIG. 23B) illustrates a next step (Metal-1 Mask and Etch) in the overall process of forming a self-aligned buried contact etch stop layer (CESL).

Contact holes 696a . . . 696d are formed through the ILD 694. This is done with a mask, and here is where misalignments may occur.

Next the contact holes are filled (with a conductive material, such as metal). And, a pattern of interconnects 698a . . . 698d (Metal-1, M1) may be provided.

The contact hole 696c is shown as being misaligned, stopping on the CESL 680. Since the contact (696c) cannot reach the silicon 512, and as long as it does substantially land on the bitline (646), the misalignment is not a concern. Optionally, the width of the contact holes 696c is such that even in the misaligned case, a full overlap with the bitline (646) is achieved. The portion that land on CESL (680) is not a concern since the CESL is self aligned to the bitline. The full coverage of the contacts by the bitlines may, if necessary, eliminate the use of an additional mask to implant into the contacts.

While a number of exemplary aspects and embodiments have been discussed above, those of skill in the art will recognize certain modifications, permutations, additions and sub-combinations thereof. It is therefore intended that the following appended claims and claims hereafter introduced be interpreted to include all such modifications, permutations, additions and sub-combinations.

What is claimed is:

1. A semiconductor device comprising:
spaced-apart diffusions selected from the group consisting of silicides, metals, raised diffusions and buried diffusions; and
a self-aligned buried contact etch stop layer (CESL) between adjacent diffusions.

2. The semiconductor device of claim 1, wherein:
the diffusions comprise bitlines; and
the semiconductor device comprises a memory array.

3. The semiconductor device of claim 1, wherein:
the CESL comprises nitride.

4. The semiconductor device of claim 1, wherein:
the CESL comprises a material that is more resistant to etch than a material on top of the CESL.

5. The semiconductor device of claim 4 where the material on top of the CESL is an Inter Layer Dielectric (ILD) through which a contact opening may be made.

6. The semiconductor device of claim 5, wherein:
the widths of the bitline contacts may be made sufficiently large to overlap the self aligned CESL thereby ensuring full coverage of the bitlines by the contacts.

7. The semiconductor device of claim 1, wherein:
the semiconductor device comprises a non-volatile memory (NVM) device.

8. The semiconductor device of claim 6, wherein:
the NVM devices are selected from the group consisting of NROM, SONOS, SANOS, MANOS, TANOS and Floating Gate (FG) devices.

9. The semiconductor device of claim 1, wherein:
the CESL is self-aligned to the diffusions.

10. The semiconductor device of claim 1, wherein:
the CESL is completely enclosed within oxide.

11. The semiconductor device of claim 1, wherein:
the CESL is bounded on all sides by oxide and/or polysilicon.

12. The semiconductor device of claim 1, further comprising:
shallow trench isolation (STI) under the CESL.

13. The semiconductor device of claim 1, wherein:
the CESL is formed by an oxide/CESL dep-etch-dep process.

14. The semiconductor device of claim 1, wherein:
the CESL is configured from a hard mask.

15. The semiconductor device of claim 1, wherein:
the semiconductor device comprises an array of memory cells;
the diffusions comprise a plurality of bitlines extending through a contact area in the array;
memory devices connected between the bitlines in a cell area adjacent to the contact area; and
a buried contact etch stop layer (CESL) disposed between adjacent bitlines.

16. The array of claim 15, wherein:
the bitlines are selected from the group consisting of silicides, metals, raised diffusions or buried bitlines.

17. The array of claim 15, further comprising:
oxide disposed under the buried CESL.

18. The array of claim 15, further comprising:
oxide surrounding at least a portion of the buried CESL.

19. The array of claim 15, further comprising:
polysilicon disposed under the buried CESL.

20. The array of claim 15, further comprising:
polysilicon surrounding at least a portion of the buried CESL.

21. The array of claim 15, further comprising:
oxide disposed over the buried CESL.

22. The array of claim 15, further comprising:
STI trenches disposed between the bitlines.

23. The array of claim 15, wherein:
the memory cells comprise NVM devices.

24. The array of claim 22, wherein:
the NVM devices are selected from the group consisting of NROM, SONOS, SANOS, MANOS, TANOS and Floating Gate (FG) devices.
